(19) United States
(12) Patent Application Publication
(10) Pub. No.: US 2023/0040798 A1
(43) Pub. Date: Feb. 9, 2023

(54) OPTICAL FILTER, WAVELENGTH TUNABLE LASER ELEMENT, WAVELENGTH TUNABLE LASER MODULE, METHOD OF CONTROLLING WAVELENGTH TUNABLE LASER MODULE, AND COMPUTER-READABLE NON-TRANSITORY MEDIUM

(71) Applicants: SUMITOMO ELECTRIC INDUSTRIES, LTD., Osaka-shi (JP); NATIONAL UNIVERSITY CORPORATION HOKKAIDO UNIVERSITY, Sapporo-shi (JP)

(72) Inventors: Naoya KONO, Osaka-shi (JP); Naoki FUJIWARA, Osaka-shi (JP); Kunimasa SAITOH, Sapporo-shi (JP); Takeshi FUJISAWA, Sapporo-shi (JP); Takanori SATO, Sapporo-shi (JP)

(73) Assignees: SUMITOMO ELECTRIC INDUSTRIES, LTD., Osaka-shi (JP); NATIONAL UNIVERSITY CORPORATION HOKKAIDO UNIVERSITY, Sapporo-shi (JP)

(21) Appl. No.: 17/860,301

(22) Filed: Jul. 8, 2022

(30) Foreign Application Priority Data
Jul. 20, 2021 (JP) 2021-119770
Dec. 6, 2021 (JP) 2021-197850
May 24, 2022 (JP) 2022-084531

(51) Int. Cl. H01S 5/0687; H01S 5/10; H01S 5/026

(52) U.S. Cl. CPC H01S 5/0687; H01S 5/101; H01S 5/026

(57) ABSTRACT

An optical filter includes a first loop mirror, a second loop mirror, a first waveguide optically coupled to the first loop mirror and the second loop mirror, and a first access waveguide. The first loop mirror includes a first loop waveguide and a first multiplexer/demultiplexer. The second loop mirror includes a second loop waveguide and a second multiplexer/demultiplexer. The first loop waveguide is optically coupled to the first multiplexer/demultiplexer. The second loop waveguide is optically coupled to the second multiplexer/demultiplexer. The first waveguide is optically coupled to the first multiplexer/demultiplexer and the second multiplexer/demultiplexer. The first access waveguide is optically coupled to the first waveguide.

### CROSS REFERENCE TO RELATED APPLICATIONS

This application claims priority based on Japanese Patent Application No. 2021-119770 filed on Jul. 20, 2021, Japanese Patent Application No. 2021-197850 filed on Dec. 6, 2021, and Japanese Patent Application No. 2022-084531 filed on May 24, 2022, and the entire contents of the Japanese patent applications are incorporated herein by reference.

### TECHNICAL FIELD

The present disclosure relates to an optical filter, a wavelength tunable laser element, a wavelength tunable laser module, a method of controlling a wavelength tunable laser module, and a computer-readable non-transitory medium.

### BACKGROUND

Wavelength tunable laser elements having a gain section and a filter for reflecting light are known. There is a technique of forming a filter by a plurality of ring resonators and a loop mirror (for example, Patent Document 1). There is a technique of forming a filter by optically coupling a waveguide branched into two and a ring resonator (for example, Patent Document 2). The oscillation wavelength of the laser element is adjusted by controlling the characteristics of the filter and changing the phase of light.
[Patent Document 1] Japanese Unexamined Patent Application Publication No. 2016-102926
[Patent Document 2] International Patent Publication No. WO 2019/159808

### SUMMARY OF THE DISCLOSURE

An optical filter according to the present disclosure includes a first loop mirror, a second loop mirror, a first waveguide optically coupled to the first loop mirror and the second loop mirror, and a first access waveguide. The first loop mirror includes a first loop waveguide and a first multiplexer/demultiplexer. The second loop mirror includes a second loop waveguide and a second multiplexer/demultiplexer. The first loop waveguide is optically coupled to the first multiplexer/demultiplexer. The second loop waveguide is optically coupled to the second multiplexer/demultiplexer. The first waveguide is optically coupled to the first multiplexer/demultiplexer and the second multiplexer/demultiplexer. The first access waveguide is optically coupled to the first waveguide.

A wavelength tunable laser element according to the present disclosure includes a gain section and two optical filters. The two optical filters are the above optical filters. Intervals between resonant wavelengths of the two optical filters differ from each other. The gain section has an optical gain and is optically coupled to the first access waveguide of each of the two optical filters.

A wavelength tunable laser module according to the present disclosure includes the above wavelength tunable laser element, a light source configured to emit light into a second access waveguide of the wavelength tunable laser element, and a light-receiving element optically coupled to a second access waveguide of the wavelength tunable laser element.

A method of controlling the wavelength tunable laser module according to the present disclosure includes a step of emitting light from the light source into a second access waveguide of the wavelength tunable laser element and a step of controlling, based on an intensity of light passing through the second access waveguide, a wavelength of light propagating in the second access waveguide.

### BRIEF DESCRIPTION OF THE DRAWINGS

FIG. 1A is a plan view illustrating an optical filter according to a first embodiment.

FIG. 1B is a cross-sectional view along line A-A of FIG. 1A.

FIG. 2A is a diagram illustrating a reflection characteristic of an optical filter.

FIG. 2B is a diagram illustrating a reflection characteristic of an optical filter.

FIG. 3 is a plan view illustrating an optical filter according to a second embodiment.

FIG. 4A is a diagram illustrating characteristics of an optical filter.

FIG. 4B is a diagram illustrating characteristics of an optical filter.

FIG. 4C is a diagram illustrating characteristics of an optical filter.

FIG. 5A is a diagram illustrating characteristics of an optical filter.

FIG. 5B is a diagram illustrating characteristics of an optical filter.

FIG. 5C is a diagram illustrating characteristics of an optical filter.

FIG. 6 is a plan view illustrating an optical filter according to a first modification.

FIG. 7 is a plan view illustrating an optical filter according to a second modification.

FIG. 8 is a plan view illustrating a wavelength tunable laser element according to a third embodiment.

FIG. 9A is a cross-sectional view taken along line B-B of FIG. 8.

FIG. 9B is a cross-sectional view taken along line C-C of FIG. 8.

FIG. 10 is a diagram illustrating reflection characteristics of an optical filter.

FIG. 11 is a plan view illustrating a wavelength tunable laser element according to a fourth embodiment.

FIG. 12 is a cross-sectional view taken along line D-D of FIG. 11.

FIG. 13 is a cross-sectional view taken along line E-E of FIG. 11.

FIG. 14 is a diagram illustrating a wavelength tunable laser module according to a sixth embodiment.

FIG. 15 is a block diagram illustrating a hardware configuration of a controller.

FIG. 16A is a flowchart illustrating the process performed by the controller.

FIG. 16B is a flowchart illustrating the process performed by the controller.

FIG. 17 is a diagram illustrating a spectrum of transmittance.

FIG. 18A is a diagram illustrating a spectrum of transmittance.

FIG. 18B is a flowchart illustrating the process performed by the controller.

FIG. 19 is a plan view illustrating an optical filter according to a seventh embodiment.

FIG. 20A is an enlarged view of the multiplexer/demultiplexer.

FIG. 20B is an enlarged view of the region.

FIG. 21A is a diagram illustrating an optical filter.

FIG. 21B is a diagram illustrating an optical filter.

FIG. 22A is a diagram illustrating characteristics of a multiplexer/demultiplexer.

FIG. 22B is a diagram illustrating characteristics of a multiplexer/demultiplexer.

FIG. 23A is a diagram illustrating a frequency characteristic of an optical filter.

FIG. 23B is a diagram illustrating a frequency characteristic of an optical filter.

FIG. 24A is a diagram illustrating a frequency characteristic of an optical filter.

FIG. 24B is a diagram illustrating a frequency characteristic of an optical filter.

### DETAILED DESCRIPTION OF THE DISCLOSURE

The characteristics of the filter used in the wavelength tunable laser element may change over time due to temperature changes, current injection, and the like. When the characteristics of the filter cannot be monitored, it is difficult to accurately control the characteristics of the filter, and the oscillation wavelength becomes unstable. Accordingly, it is an object of the present disclosure to provide an optical filter, a wavelength tunable laser element, a wavelength tunable laser module, and a method of controlling a wavelength tunable laser module, which are capable of monitoring characteristics.

### Description of Embodiments of the Present Disclosure

First, embodiments of the present disclosure will be listed and described.

(1) An optical filter according to an aspect of the present disclosure includes a first loop mirror, a second loop mirror, a first waveguide optically coupled to the first loop mirror and the second loop mirror and a first access waveguide. The first loop mirror includes a first loop waveguide and a first multiplexer/demultiplexer. The second loop mirror includes a second loop waveguide and a second multiplexer/demultiplexer. The first loop waveguide is optically coupled to the first multiplexer/demultiplexer. The second loop waveguide is optically coupled to the second multiplexer/demultiplexer. The first waveguide is optically coupled to the first multiplexer/demultiplexer and the second multiplexer/demultiplexer. The first access waveguide is optically coupled to the first waveguide. When light is incident on the first access waveguide, light having a resonance wavelength is reflected by the first access waveguide. Light having a wavelength other than the resonance wavelength is transmitted. The reflected and transmitted light propagating through the first access waveguide can be used to monitor the characteristics of the optical filter.

(2) The optical filter may include a second waveguide optically coupled to the first loop mirror and the second loop mirror and a second access waveguide. The second waveguide may be optically coupled to the first multiplexer/demultiplexer and the second multiplexer/demultiplexer. The second access waveguide may be optically coupled to the second waveguide. The characteristics of the optical filter can be monitored using reflected and transmitted light propagating through one of the first access waveguide and the second access waveguide.

(3) A shape of the first multiplexer/demultiplexer may be symmetrical, a shape of the second multiplexer/demultiplexer may be symmetrical, and a shape of the first waveguide and a shape of the second waveguide may be symmetrical to each other. The resonance wavelengths of the resonance modes excited in the first access waveguide are equal to the resonance wavelengths of the resonance modes excited in the second access waveguide. The FSR of the resonance mode excited by the first access waveguide is equal to the FSR of the resonance mode excited by the second access waveguide. The characteristics of the optical filter can be monitored by measuring the resonance wavelengths and FSR of light propagating through one of the first access waveguide and the second access waveguide.

(4) The first multiplexer/demultiplexer and the second multiplexer/demultiplexer may be 2×2 multi-mode interference waveguides or directional couplers. Light incident from the first waveguide to the first loop mirror and the second loop mirror is reflected back to the first waveguide. The resonant mode is excited in the first access waveguide coupled to the first waveguide. Light incident from the second waveguide to the first loop mirror and the second loop mirror is reflected back to the second waveguide. The resonant mode is excited in the second access waveguide coupled to the second waveguide. One of the two resonant modes can be extracted from the first access waveguide and the other from the second access waveguide.

(5) The first multiplexer/demultiplexer and the second multiplexer/demultiplexer may be directional couplers each including two waveguides. A distance between the two waveguides of the first multiplexer/demultiplexer on a side of the first loop waveguide and the distance on a side of the first waveguide and the second waveguide may be greater than the distance in a central part of the first multiplexer/demultiplexer. A distance between the two waveguides of the second multiplexer/demultiplexer on a side of the second loop waveguide and the distance on a side of the first waveguide and the second waveguide may be greater than the distance in a central part of the second multiplexer/demultiplexer. In the first demultiplexer and the second demultiplexer, the division of light is nearly equal over a wide wavelength band. The wavelength dependence of crosstalk is improved, and crosstalk can be suppressed to be low in a wide wavelength band.

(6) The two waveguides of the first multiplexer/demultiplexer may have a bend on the side of the first loop waveguide and have a bend on the side of the first waveguide and the second waveguide. The two waveguides of the second multiplexer/demultiplexer may have a bend on the side of the second loop waveguide and have a bend on the side of the first waveguide and the second waveguide. In the first demultiplexer and the second demultiplexer, the distance between the two waveguides at the bend is larger than the distance between the two waveguides at the central portion. In the first demultiplexer and the second demultiplexer, the division of light is nearly equal over a wide wavelength band. The wavelength dependence of crosstalk is improved, and crosstalk can be suppressed to be low in a wide wavelength band.

(7) The central part of the two waveguides of the first multiplexer/demultiplexer may be curvilinear. As compared with the distance between the waveguides in the curved portion of the central portion, the distance in the portion away from the central portion is larger. In the first multiplexer/demultiplexer, the division of light is nearly equal over a wide wavelength band. The wavelength dependence of crosstalk is improved, and crosstalk can be suppressed to be low in a wide wavelength band.

(8) The optical filter may include a phase adjusting section disposed in at least one of the first loop waveguide and the second loop waveguide, the phase adjusting section being configured to adjust a phase of light propagating in the at least one of the first loop waveguide and the second loop waveguide. By adjusting the phase of light, the wavelength of light can be changed.

(9) The first waveguide, the second waveguide, the first loop waveguide, the second loop waveguide, the first access waveguide, and the second access waveguide may be formed of silicon. The loss of light can be suppressed.

(10) The first waveguide, the second waveguide, the first loop waveguide, the second loop waveguide, the first access waveguide, and the second access waveguide may include a mesa, and the mesa may include a first cladding layer, a core layer and a second cladding layer. The first cladding layer, the core layer and the second cladding layer may be formed of a group III-V compound semiconductor. The first cladding layer, the core layer and the second cladding layer may be stacked in this order to form the mesa. The loss of light can be suppressed.

(11) The phase adjustment unit may be a heater that generates heat in response to an electric signal inputted on the heater. The refractive index is changed by the heat so that the phase of light can be adjusted and the wavelength of light can be changed.

(12) A wavelength tunable laser element includes a gain section and two optical filters. Each of the two optical filters is the above optical filter. Intervals between resonant wavelengths of the two optical filters differ from each other. The gain section has an optical gain and is optically coupled to the first access waveguide of each of the two optical filters. An output light from the gain section propagates through the first access waveguide and is reflected by the optical filter. The wavelength tunable laser element performs laser oscillation by the vernier effect of the two optical filters. Light propagating through the second access waveguide can be used to monitor the characteristics of the optical filter.

(13) The two optical filters may be formed on a substrate. The gain section and the substrate may be butt joined to each other. The wavelength tunable laser element may include a reflection mirror disposed opposite to the substrate with respect to the gain section. The output light from the gain section propagates through the first access waveguide and is reflected by the optical filter and the reflection mirror. The wavelength tunable laser element performs laser oscillation. Light propagating through the second access waveguide can be used to monitor the characteristics of the optical filter.

(14) The wavelength tunable laser element may include a substrate made of a III-V group compound semiconductor. The gain section and the two optical filters may be monolithically integrated on the substrate. A first one of the two optical filters may be positioned on a side of a first end portion of the gain section. A second one of the two optical filters may be positioned on a side of a second end portion of the gain section. The output light of the gain section propagates through the first access waveguide and is reflected by the two optical filters. The wavelength tunable laser element performs laser oscillation. Light propagating through the second access waveguide can be used to monitor the characteristics of the optical filter.

(15) The two optical filters may be formed on a substrate. The first waveguide, the second waveguide, the first loop waveguide, the second loop waveguide, the first access waveguide, and the second access waveguide may be silicon waveguides formed on the substrate. A first one of the two optical filters may be positioned on a side of a first end portion of the gain section. A second one of the two optical filters may be positioned on a side of a second end portion of the gain section. The gain section may be bonded to a surface of the substrate. The output light of the gain section propagates through the first access waveguide and is reflected by the two optical filters. The wavelength tunable laser element performs laser oscillation. Light propagating through the second access waveguide can be used to monitor the characteristics of the optical filter.

(16) A wavelength tunable laser module includes the above wavelength tunable laser element, a light source configured to emit light into a second access waveguide of the wavelength tunable laser element, and a light-receiving element optically coupled to a second access waveguide of the wavelength tunable laser element. The output light of the gain section propagates through the first access waveguide and is reflected by the optical filter. The wavelength tunable laser element performs laser oscillation by the vernier effect of the two optical filters. Light propagating through the second access waveguide can be used to monitor the characteristics of the optical filter.

(17) A method of controlling the above wavelength tunable laser module includes a step of emitting light from the light source into a second access waveguide of the wavelength tunable laser element, and a step of controlling, based on an intensity of light passing through the second access waveguide, a wavelength of light propagating in the second access waveguide. The output light from the gain section propagates through the first access waveguide and is reflected by the optical filter. The wavelength tunable laser element performs laser oscillation by the vernier effect of the two optical filters. Light propagating through the second access waveguide can be used to monitor the characteristics of the optical filter.

(18) The step of controlling the wavelength of light may be a step of controlling, based on the intensity of light passing through the second access waveguide, the wavelength of light propagating in the second access waveguide by using the phase adjusting section. Light propagating through the second access waveguide can be used to monitor the characteristics of the optical filter.

(19) The step of controlling the wavelength of light may be a step of controlling the wavelength of light propagating in the second access waveguide by controlling, based on the intensity of light passing through the second access waveguide, the wavelength of light emitted from the light source. Light propagating through the second access waveguide can be used to monitor the characteristics of the optical filter.

(20) A computer-readable, non-transitory medium storing a program for controlling the above wavelength tunable laser module that causes a computer to execute a process. The process includes the steps of: emitting light from a light source into a second access waveguide of the wavelength tunable laser element; and controlling, based on an intensity of light passing through the second access waveguide, a wavelength of light propagating in the second access waveguide. The output light of the gain section propagates through the first access waveguide and is reflected by the optical filter. The wavelength tunable laser element performs laser oscillation by the vernier effect of the two optical filters. Light propagating through the second access waveguide can be used to monitor the characteristics of the optical filter.

### Details of Embodiment of the Present Disclosure

It should be noted that the present disclosure is not limited to these examples, but is defined by the scope of claims and intended to include all modifications within the meaning and scope equivalent to the scope of claims.

### First Embodiment

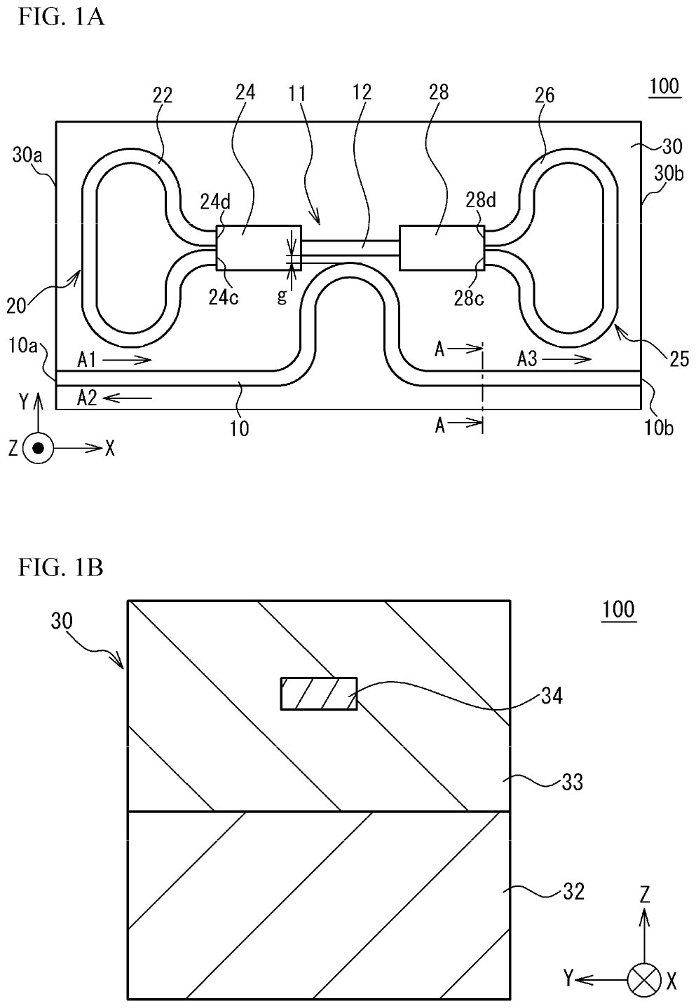

FIG. 1A is a plan view illustrating an optical filter 100 according to a first embodiment. As illustrated in FIG. 1A, optical filter 100 is a silicon-based filter element, and includes an access waveguide 10 (a first access waveguide), a waveguide 12 (a first waveguide), and two loop mirrors 20 and 25.

An upper surface of a substrate 30 extends in an XY plane. Two sides of substrate 30 extend in an X-axis direction. Two sides of substrate 30 extend in a Y-axis direction. The X-axis direction is orthogonal to the Y-axis direction. A Z-axis direction is a thickness direction of substrate 30 and is orthogonal to the X-axis direction and the Y-axis direction. One end portion of substrate 30 in the X-axis direction is referred to as an end portion 30a, and the other end portion is referred to as an end portion 30b.

Access waveguide 10, waveguide 12, and two loop mirrors 20 and 25 are formed on substrate 30. Loop mirror 20 (a first loop mirror) is located on the side of end portion 30a of substrate 30. Loop mirror 25 (a second loop mirror) is located on the side of end portion 30b and faces loop mirror 20. Waveguide 12 extends in the X-axis direction, is located between loop mirror 20 and loop mirror 25, and is connected to loop mirror 20 and loop mirror 25.

Loop mirror 20 includes a loop waveguide 22 (a first loop waveguide) and a multiplexer/demultiplexer 24 (a first multiplexer/demultiplexer). Loop mirror 25 includes a loop waveguide 26 (a second loop waveguide) and a multiplexer/demultiplexer 28 (a second multiplexer/demultiplexer). The two loop mirrors 20 and 25 and waveguide 12 form a resonator 11.

Multiplexer/demultiplexer 24 and multiplexer/demultiplexer 28 in the example of FIG. 1A are, for example, one-input two-output (1×2) Multi Mode Interference (MMI) waveguides of 3 dB. Multiplexer/demultiplexer 24 and multiplexer/demultiplexer 28 may be, for example, Y-branch waveguides other than the 1×2 MMI. Multiplexer/demultiplexer 24 and multiplexer/demultiplexer 28 each have one input end and two output ends. A first end portion of waveguide 12 is optically coupled to an input end of multiplexer/demultiplexer 24. A second end portion of waveguide 12 is optically coupled to an input end of multiplexer/demultiplexer 28.

Loop waveguide 22 of loop mirror 20 is a loop-shaped optical waveguide. A first end portion of loop waveguide 22 is optically coupled to a first output end 24c of multiplexer/demultiplexer 24. A second end portion of loop waveguide 22 is optically coupled to a second output end 24d of multiplexer/demultiplexer 24. Loop mirror 20 has a reflective structure that reflects light to the input end of multiplexer/demultiplexer 24 when light is input from the input end of multiplexer/demultiplexer 24.

Loop waveguide 26 of loop mirror 25 is a loop-shaped optical waveguide. A first end portion of loop waveguide 26 is optically coupled to a first output end 28c of multiplexer/demultiplexer 28. A second end portion of loop waveguide 26 is optically coupled to a second output end 28d of multiplexer/demultiplexer 28. Loop mirror 25 has a reflective structure that reflects light to the input end of multiplexer/demultiplexer 28 when light is input from the input end of multiplexer/demultiplexer 28.

Access waveguide 10 and waveguide 12 are arranged in the Y-axis direction. An end portion 10a of access waveguide 10 is located at the end portion 30a of substrate 30. The other end portion 10b of access waveguide 10 is located at the end portion 30b of substrate 30. Access waveguide 10 extends in the X-axis direction and is curved so as to approach waveguide 12. Access waveguide 10 is spaced a distance g from waveguide 12 and is optically coupled to waveguide 12. The distance g is, for example, several hundred nm.

FIG. 1B is a cross-sectional view along line A-A of FIG. 1A illustrating a cross-section of access waveguide 10. The cross-sections of waveguide 12 and loop waveguides 22 and 26 the same as that of FIG. 1B. Substrate 30 is an SOI (Silicon on Insulator) substrate and includes a substrate 32, a cladding layer 33, and a waveguide core 34. Substrate 30 is formed of, for example, Si. Cladding layer 33 is formed of, for example, silicon oxide (SiO₂) and covers one surface of substrate 30. Waveguide core 34 is formed of, for example, Si, is spaced apart from substrate 30, and is embedded inside cladding layer 33. A distance from an upper surface of substrate 32 to a lower end of waveguide core 34 is, for example, 2 μm. A width of waveguide core 34 in the Y-axis direction is, for example, 0.44 μm. A thickness of waveguide core 34 is, for example, 0.22 μm.

One of end portions 10a and 10b of access waveguide 10 (for example, end portion 10a) serves as an incident port of optical filter 100. Light from a light source (not illustrated) disposed outside optical filter 100 enters optical filter 100 through end portion 10a as indicated by an arrow A1 in FIG. 1A. When light enters access waveguide 10, a resonance mode is excited in resonator 11. As indicated by an arrow A2 in FIG. 1A, the light (a reflected light) having the resonance wavelengths is reflected toward end portion 10a of access waveguide 10 and is emitted from end portion 10a to the outside of optical filter 100. As indicated by an arrow A3, light (a transmitted light) having wavelengths other than the resonance wavelengths passes through optical filter 100 and is emitted from end portion 10b of access waveguide 10 to the outside of optical filter 100.

More specifically, light propagates through access waveguide 10 and transfers from access waveguide 10 to waveguide 12. Light propagating in waveguide 12 is divided into two output ends 24c and 24d of multiplexer/demultiplexer 24 and propagates in loop waveguide 22. The intensity ratio of the divided lights is 1:1 and phases of the divided lights are equal to each other. The divided light propagating clockwise in loop waveguide 22 and the divided light propagating counterclockwise in loop waveguide 22 are merged at the same phase and enter waveguide 12 from multiplexer/demultiplexer 24.

Light propagating in waveguide 12 is divided into two output ends 28c and 28d of multiplexer/demultiplexer 28 and propagates in loop waveguide 26. Light propagating clockwise in loop waveguide 26 and light propagating counterclockwise in loop waveguide 26 are merged at the same phase and enter waveguide 12 from multiplexer/demultiplexer 28.

Each of the resonance wavelengths of resonator 11 is a wavelength at which a change in the phase of light when light makes one round of the two loop mirrors 20 and 25 becomes 2πn (n is an integer). Light having the resonant wavelengths passes from waveguide 12 to access waveguide 10 and is reflected toward end portion 10a of access waveguide 10 as indicated by arrow A2 in FIG. 1A. Lights having wavelengths other than the resonance wavelengths are emitted from end portion 10b of access waveguide 10 as indicated by an arrow A3 in FIG. 1A.

That is, optical filter 100 is a filter that reflects light having a resonance wavelength and transmits light having a wavelength other than the resonance wavelength. Characteristics of optical filter 100 can be monitored by receiving reflected light or transmitted light of optical filter 100 with a light-receiving element such as a photodiode.

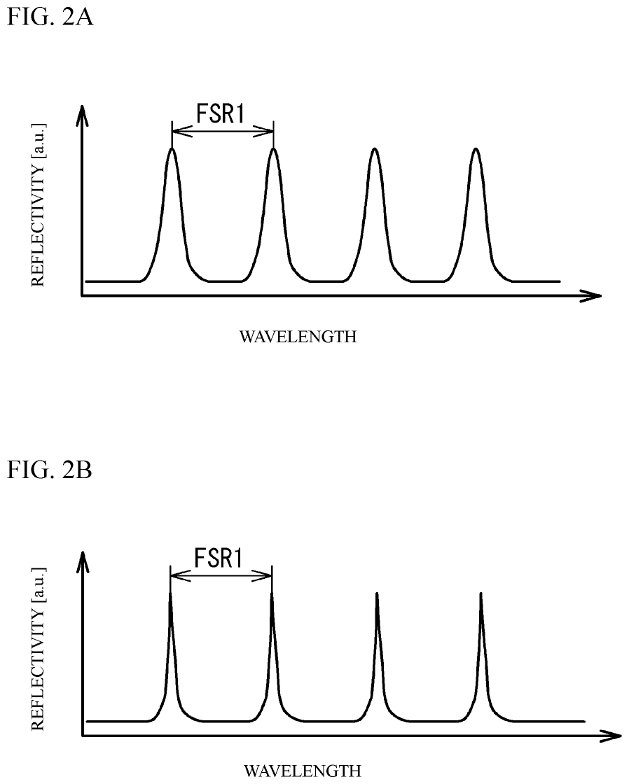

FIG. 2A and FIG. 2B are examples of reflection characteristics of optical filter 100. The horizontal axis represents the wavelength of light. The vertical axis represents the reflectivity of optical filter 100. As illustrated in FIGS. 2A and 2B, the reflectivity shows peaks at the resonance wavelengths of resonator 11. The interval between two adjacent resonance wavelengths (Free Spectral Range: FSR) is determined by an optical path length of resonator 11 (waveguide 12 and loop mirrors 20 and 25). The resonance wavelengths in FIG. 2A coincide with the resonance wavelengths in FIG. 2B. The FSR in FIG. 2A is equal to the FSR in FIG. 2B. A value of FSR of FIG. 2A and FIG. 2B is denoted by FSR1.

On the other hand, a width of the peak in FIG. 2A is wider than that in FIG. 2B. The width of the peak is determined by a Q value of resonator 11. The Q value is determined by a coupling ratio between access waveguide 10 and resonator 11. When the distance g between access waveguide 10 and waveguide 12 is reduced, the coupling ratio between access waveguide 10 and waveguide 12 increases, and the Q value decreases. When the Q value is small, the peak is wide and gentle as illustrated in FIG. 2A. When the distance g is increased, the coupling ratio decreases and the Q value increases. Then, as illustrated in FIG. 2B, the peak becomes narrow and sharp.

According to the first embodiment, optical filter 100 includes access waveguide 10, waveguide 12, and loop mirrors 20 and 25. Waveguide 12 and loop mirrors 20 and 25 are optically coupled to form resonator 11. When light is incident on end portion 10a of access waveguide 10, light having the resonance wavelength is reflected by resonator 11 and is emitted from end portion 10a of access waveguide 10. Light having a wavelength other than the resonance wavelength passes through optical filter 100 and is emitted from end portion 10b of access waveguide 10. The characteristics of optical filter 100 can be monitored by detecting reflected light or transmitted light of optical filter 100.

The reflectivity or transmittance of optical filter 100 is measured while changing the wavelength of light incident on access waveguide 10. As illustrated in FIG. 2A and FIG. 2B, the wavelengths at which the reflectivity becomes maximum are resonance wavelengths. By measuring the reflectivity spectrum, the resonance wavelength and the interval between peaks of reflectivity (i.e. FSR) can be directly measured. By changing the distance g between access waveguide 10 and waveguide 12, the Q value and the coupling ratio can be adjusted. Thus, the shape of the peak can be varied as exemplified in FIG. 2A and FIG. 2B. The characteristics of optical filter 100 may be monitored using the transmitted light. The wavelength at which the transmittance becomes minimum is the resonance wavelength.

The refractive index of the optical waveguide in optical filter 100 may change over time. The change in the refractive index changes the characteristics of optical filter 100. Light propagating through access waveguide 10 can be used to directly monitor the characteristics of optical filter 100. By measuring the reflectivity, it is possible to accurately detect a change in characteristics such as a shift of a resonance wavelength.

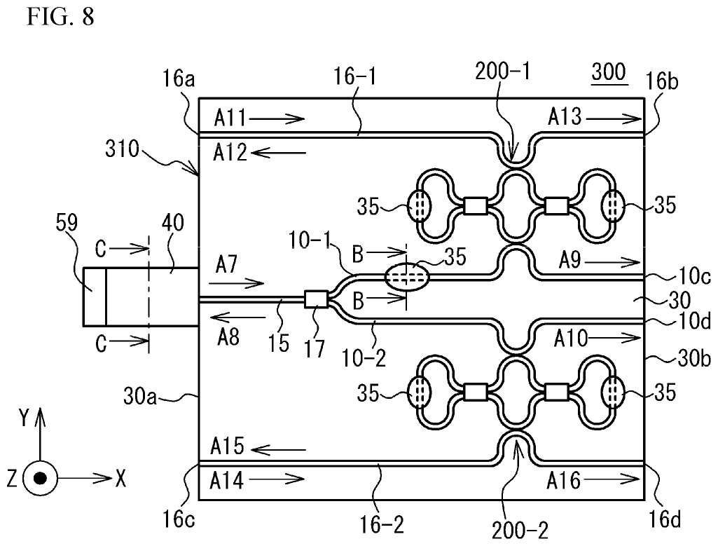

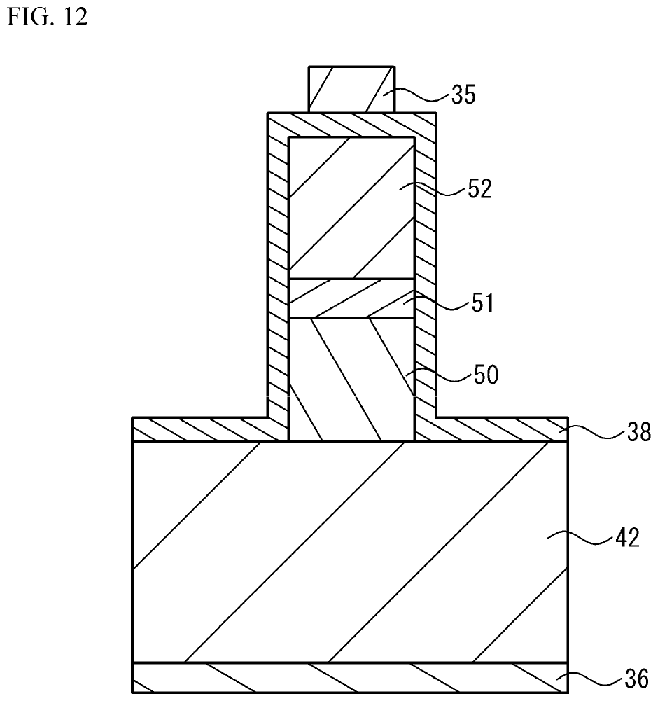

As illustrated in FIG. 1B, the optical waveguide of optical filter 100 has waveguide core 34 of Si. Waveguide core 34 is surrounded by cladding layer 33. The refractive index of Si is about 3.5. The refractive index of SiO₂ is about 1.4. Light can be strongly confined in waveguide core 34 which has a higher refractive index than cladding layer 33. Optical losses in bent optical waveguides, such as access waveguide 10, loop waveguides 22 and 26, are suppressed. The optical waveguide of optical filter 100 may be the waveguide made of silicon as illustrated in FIG. 1B, or a waveguide made of a compound semiconductor as described in FIG. 12. As illustrated in FIG. 8, an electrode 35 may be provided on the optical waveguide. The shape of loop waveguide 22 may be the same as or different from that of loop waveguide 26.

### Second Embodiment

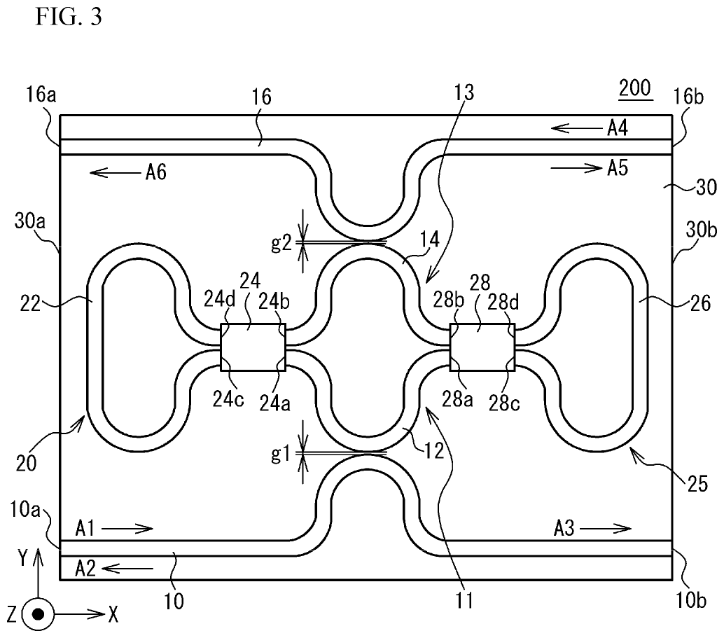

FIG. 3 is a plan view illustrating an optical filter 200 according to a second embodiment. Description of the same configuration as in the first embodiment will be omitted. As illustrated in FIG. 3, optical filter 200 includes two access waveguides 10 and 16, two waveguides 12 and 14, and two loop mirrors 20 and 25. Waveguide 12 and loop mirrors 20 and 25 form resonator 11. Waveguide 14 and loop mirrors 20 and 25 form a resonator 13. The optical waveguide of optical filter 200 has the same configuration as that of FIG. 1B.

Access waveguide 10, waveguide 12, waveguide 14, and access waveguide 16 are arranged in this order from one end portion (lower end portion in FIG. 3) of substrate 30 in the Y-axis direction toward the other end portion (upper end portion in FIG. 3). Access waveguide 10 and waveguide 12 are curved so as to approach each other. Access waveguide 10 is optically coupled to waveguide 12 and spaced apart from waveguide 12 by a distance g1. Access waveguide 16 and waveguide 14 are curved so as to approach each other. Access waveguide 16 is optically coupled to waveguide 14 and spaced apart from waveguide 14 by a distance g2.

End portion 10a of access waveguide 10 and an end portion 16a of access waveguide 16 are located at end portion 30a of substrate 30. End portion 10b of access waveguide 10 and an end portion 16b of access waveguide 16 are located at end portion 30b of substrate 30.

Waveguides 12 and 14 are located between loop mirror 20 and loop mirror 25 in the X-axis direction and are connected to loop mirror 20 and loop mirror 25. Waveguide 12 and waveguide 14 are symmetrical to each other in the Y-axis direction (vertical direction in FIG. 3) in which waveguide 12 and waveguide 14 are aligned. In other words, waveguide 12 and waveguide 14 are symmetrical with respect to the X axis. That is, when waveguide 14 is folded with respect to the X axis, waveguide 14 overlaps waveguide 12.

Multiplexer/demultiplexer 24 and multiplexer/demultiplexer 28 are 2×2 MMI couplers of 3 dB. The first end portion of waveguide 12 is optically coupled to a first input end 24a of multiplexer/demultiplexer 24. The second end portion of waveguide 12 is optically coupled to a first input end 28a of multiplexer/demultiplexer 28. A first end portion of waveguide 14 is optically coupled to a second input end 24b of multiplexer/demultiplexer 24. A second end portion of waveguide 14 is optically coupled to a second input end 28b of multiplexer/demultiplexer 28.

The shape of multiplexer/demultiplexer 24 is symmetrical in the vertical direction of FIG. 3. That is, the shape of multiplexer/demultiplexer 24 is symmetrical with respect to the X-axis. The shape of multiplexer/demultiplexer 28 is vertically symmetrical similar to multiplexer/demultiplexer 24.

Light is incident on one end portion (for example, end portion 10a) of access waveguide 10 as indicated by an arrow A1 in FIG. 3 from a light source (not illustrated) disposed outside optical filter 200. As indicated by an arrow A4, light is incident on one end portion (for example, end portion 16b) of access waveguide 16.

Light incident on access waveguide 10 transfers to waveguide 12. Light propagating in waveguide 12 is incident on multiplexer/demultiplexer 24 and multiplexer/demultiplexer 28. Light incident on multiplexer/demultiplexer 24 from waveguide 12 is divided into two output ends 24c and 24d of multiplexer/demultiplexer 24 and propagates through loop waveguide 22. The ratio of intensities of divided lights is 1:1. The phase of light output from output end 24d is delayed by 90° with respect to the phase of light output from output end 24c. Light propagating through loop waveguide 22 clockwise from output end 24c returns to input end 24a of multiplexer/demultiplexer 24 with a phase delay of 90° and enters waveguide 12. Light propagating through loop waveguide 22 counterclockwise from output end 24d returns to input end 24a of multiplexer/demultiplexer 24 and enters waveguide 12. That is, light incident on loop waveguide 22 from waveguide 12 is reflected back to waveguide 12 through input end 24a without being incident on waveguide 14 in principle.

Light incident on multiplexer/demultiplexer 28 from waveguide 12 is distributed to two output ends 28c and 28d of multiplexer/demultiplexer 28 with an intensity ratio of 1:1 and a phase difference of 90°, and propagates through loop waveguide 26. Light incident on loop waveguide 26 from waveguide 12 is reflected into waveguide 12 without being incident on waveguide 14 in principle. Light of waveguide 12 passes to access waveguide 10 and propagates towards end portion 10a.

Light incident on access waveguide 16 is transferred to waveguide 14 and enters multiplexer/demultiplexer 24 and multiplexer/demultiplexer 28. Light incident on multiplexer/demultiplexer 24 from waveguide 14 is distributed to two output ends 24c and 24d of multiplexer/demultiplexer 24 with an intensity ratio of 1:1 and a phase difference of 90°, and propagates through loop waveguide 22. Light incident on loop waveguide 22 from waveguide 14 is reflected back into waveguide 14 without being incident on waveguide 12 in principle. Light incident on loop waveguide 26 from waveguide 14 through multiplexer/demultiplexer 28 is reflected back into waveguide 14 without being incident on waveguide 12 in principle. Light of waveguide 14 passes to access waveguide 16 and propagates towards end portion 16b.

That is, when light is incident from end portion 10a of access waveguide 10 as indicated by an arrow A1 in FIG. 3, the resonance mode of resonator 11 can be excited. The resonance mode of resonator 11 propagates through loop waveguides 22 and 26 and waveguide 12, and is reflected toward end portion 10a of access waveguide 10 as indicated by the arrow A2. The resonance mode of resonator 11 does not propagate in waveguide 14 or access waveguide 16. Of the light propagating through access waveguide 10, light having wavelengths other than the resonance wavelengths passes through optical filter 200 as indicated by an arrow A3 and is emitted from end portion 10b to the outside of optical filter 200.

When light is incident from end portion 16b of access waveguide 16 as indicated by an arrow A4, a resonance mode of resonator 13 can be excited. The resonant mode of resonator 13 propagates through loop waveguides 22 and 26, waveguide 14 and is reflected toward end portion 16b of access waveguide 16 as indicated by the arrow A5. The resonance mode of resonator 13 does not propagate in waveguide 12 or access waveguide 10. Of the light propagating through access waveguide 16, light having wavelengths other than the resonance wavelengths passes through optical filter 200 as indicated by an arrow A6 and is emitted from end portion 16a to the outside.

When multiplexer/demultiplexer 24 is symmetrical, multiplexer/demultiplexer 28 is symmetrical, and waveguide 12 and waveguide 14 are symmetrical with respect to the X axis, the resonance wavelength of the resonance mode of resonator 11 and the resonance wavelength of the resonance mode of resonator 13 coincide with each other in principle. The FSR of the resonance mode of resonator 11 and the FSR of the resonance mode of resonator 13 coincide with each other in principle. When the resonance wavelength and FSR of one of the resonance mode of resonator 11 and the resonance mode of resonator 13 are known, the resonance wavelength and FSR of the other can also be known.

Reflected light or transmitted light of optical filter 200 propagating through access waveguide 16 is detected by a light-receiving element, and the resonance wavelength and FSR of the resonance mode of resonator 13 are measured. From the result of this measurement, it is possible to monitor the resonance wavelength and FSR of the resonance mode of resonator 11 without detecting the reflected light and transmitted light of access waveguide 10. Access waveguide 16 can be used to monitor the characteristics of optical filter 200, and access waveguide 10 can be used for applications other than monitoring, such as laser oscillation.

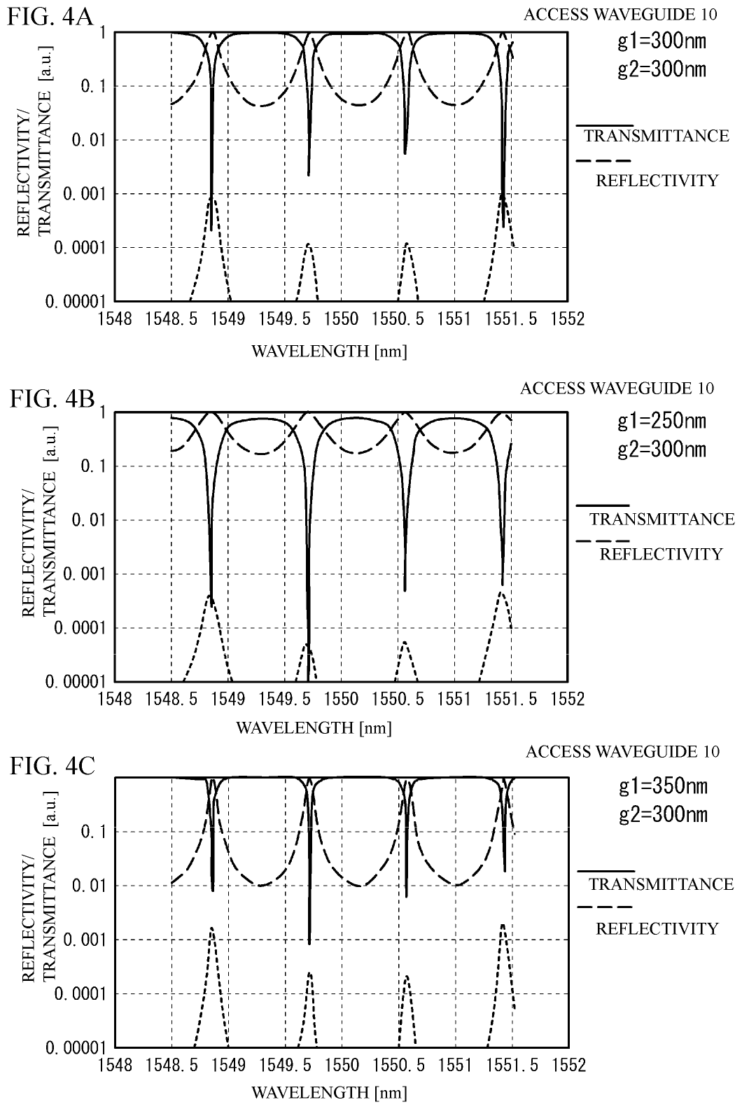

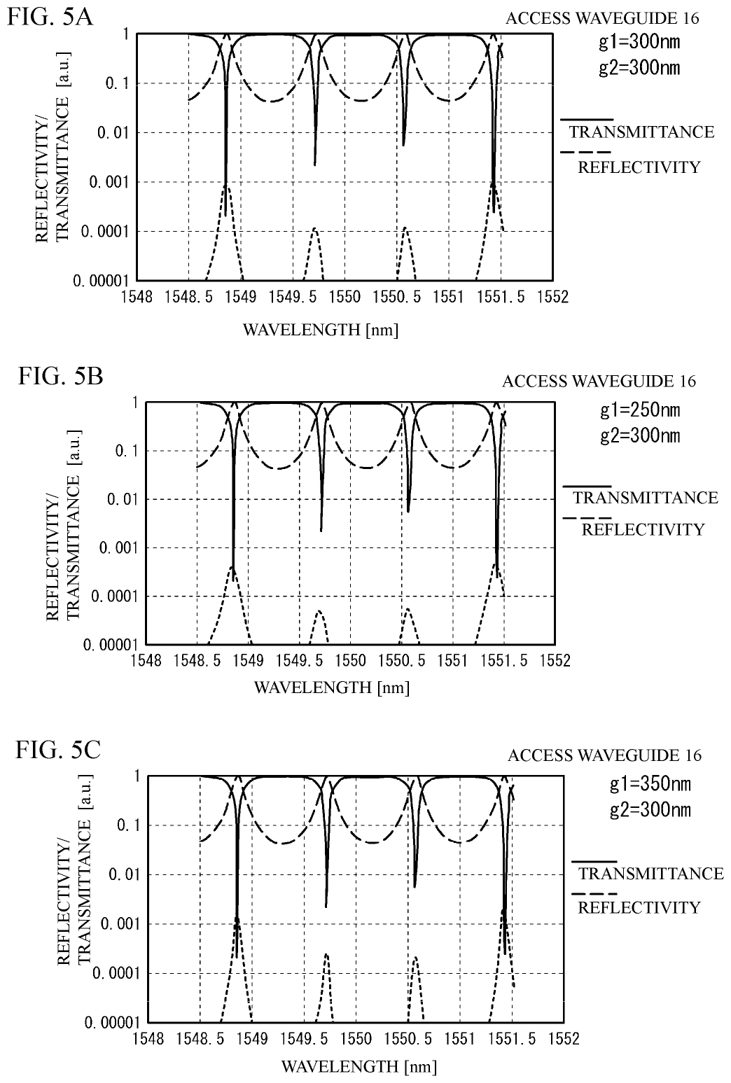

FIG. 4A to FIG. 5C are examples illustrating characteristics of optical filter 200, and are simulation results of the characteristics. The horizontal axis represents the wavelength of light. The vertical axis represents reflectivity and transmittance. The solid line represents transmittance. The broken line represents reflectivity. The dotted line represents the crosstalk between access waveguide 10 and access waveguide 16. When the distribution ratio of each of multiplexer/demultiplexer 24 and multiplexer/demultiplexer 28 changes according to the wavelength of light, crosstalk may occur. FIG. 4A to FIG. 4C are reflectivity spectra and transmittance spectra obtained using access waveguide 10. In FIG. 4A to FIG. 4C, the crosstalk is a ratio of intensity of outgoing light (arrow A5 in FIG. 3) from access waveguide 16 to intensity of incident light (arrow A3 in FIG. 3) to access waveguide 10. FIG. 5A to FIG. 5C are reflectivity spectra and transmittance spectra obtained using access waveguide 16. In FIG. 5A to FIG. 5C, the crosstalk is a ratio of outgoing light (arrow A3 in FIG. 3) from access waveguide 10 to incident light (arrow A4 in FIG. 3) to access waveguide 16.

In each example of FIG. 4A and FIG. 5A, the distance g1 between access waveguide 10 and waveguide 12 is designed as 300 nm. In each examples of FIG. 4B and FIG. 5B, the distance g1 is designed as 250 nm. In each example of FIG. 4C and FIG. 5C, the distance g1 is designed as 350 nm. In either example, the distance g2 between access waveguide 16 and waveguide 14 is 300 nm.

As illustrated in FIG. 4A to FIG. 5C, the reflectivity has local maximum values and the transmittance has local minimum values at four wavelengths in the wavelength range from 1548 nm to 1552 nm. These wavelengths are the resonance wavelengths. In the six examples, the resonant wavelengths and the FSR are equal to each other.

The peaks of the reflectivity spectrum in FIG. 4C are steeper than the peaks in FIG. 4A and FIG. 4B. The peaks of FIG. 4A are steeper than the peaks of FIG. 4B. The peaks of FIG. 4B are gentler than the peaks of FIG. 4A and FIG. 4C. When the distance g1 between access waveguide 10 and waveguide 12 is reduced, the peak shape of the spectrum becomes gentle. This is because the coupling ratio increases and the Q value decreases when the distance g1 is reduced. When the distance g1 is increased, the shape of the peak becomes steep. This is because the coupling ratio decreases and the Q value increases as the distance g1 increases. From FIG. 5A to FIG. 5C, the distance g2 between access waveguide 16 and waveguide 14 is constant. Since the coupling ratio and the Q value are constant, the shape of the peak of the spectrum is also substantially the same. Further, while the reflectivity is 1 at maximum, the crosstalk is smaller than the reflectivity by two orders of magnitude or more.

According to the second embodiment, optical filter 200 includes access waveguides 10 and 16, waveguides 12 and 14, and loop mirrors 20 and 25. Loop mirrors 20 and 25 and waveguide 12 form resonator 11. Loop mirrors 20 and 25 and waveguide 14 form resonator 13. When light is incident from end portion 10a of access waveguide 10, light having the resonance wavelength is reflected back to end portion 10a of access waveguide 10. When light is incident from end portion 16b of access waveguide 16, light of the resonance wavelength is reflected back to end portion 16b of access waveguide 16. Light having a wavelength other than the resonance wavelength is transmitted through optical filter 200 and propagates through access waveguides 10 and 16.

Characteristics of optical filter 200 can be monitored by detecting reflected light or transmitted light of optical filter 200 that propagates through one of access waveguides 10 and 16. For example, access waveguide 16 can be used for monitoring, and access waveguide 10 can be used for an application other than monitoring.

Waveguide 12 and waveguide 14 are symmetric with respect to the Y-axis direction in which waveguide 12 and waveguide 14 are aligned. The shape of multiplexer/demultiplexer 24 is symmetrical. The shape of multiplexer/demultiplexer 28 is symmetrical. The resonance wavelengths of the resonance modes of resonator 11 coincide with the resonance wavelengths of the resonance modes of resonator 13. The FSR of the resonance mode of resonator 11 coincides with the FSR of the resonance mode of resonator 13. By measuring the resonance wavelengths of the resonance modes and FSR of resonator 13 using access waveguide 16, it is possible to monitor the resonance wavelengths of the resonance modes and FSR of resonator 11. Access waveguide 10 can be used for applications other than monitoring. The shape of multiplexer/demultiplexer 24 may be point-symmetric with respect to the center of multiplexer/demultiplexer 24 itself. The shape of multiplexer/demultiplexer 28 may be point-symmetric with respect to the center of multiplexer/demultiplexer 28 itself.

The refractive index of the optical waveguide in optical filter 200 may change over time. As a result, the characteristics of optical filter 200 such as the peak wavelength (resonance wavelength) may change. Since the characteristics of optical filter 200 can be monitored using light propagating through access waveguide 16, a change in the characteristics can be accurately detected.

Multiplexer/demultiplexer 24 and multiplexer/demultiplexer 28 may be a 2×2 MMI or a directional coupler. The resonance mode excited by light incident on access waveguide 10 propagates through loop mirrors 20 and 25, waveguide 12, and access waveguide 10, but does not propagate through waveguide 14 or the access waveguide 12. The resonance mode excited by light incident on access waveguide 16 propagates through loop mirrors 20 and 25, waveguide 14, and access waveguide 16, but does not propagate through waveguide 12 or access waveguide 10. One of the two resonance modes can be extracted from one access waveguide.

The coupling ratio between access waveguide 10 and waveguide 12 is determined by the distance g1 between access waveguide 10 and waveguide 12. As illustrated from FIG. 4A to FIG. 4C, the shape of the spectrum can be changed by changing the distances g1. The coupling ratio between access waveguide 16 and waveguide 14 is determined by the distance g2 between access waveguide 16 and waveguide 14. The distances g1 can be determined independently of the distances g2. Therefore, the shape of the spectrum of resonator 11 and the shape of the spectrum of resonator 13 can be adjusted independently of each other. The coupling ratio between access waveguide 10 and waveguide 12 may be equal to or different from the coupling ratio between access waveguide 16 and waveguide 14. When light having high intensity propagates through resonators 11 and 13, a non-linear optical effect may occur, and characteristics may become unstable. The coupling ratio can be adjusted by changing the distances g1 and g2 so that the intensity of light in resonators 11 and 13 becomes appropriate. When the distribution ratio of the multiplexer/demultiplexer deviates from the design value, mixing (crosstalk) may occur between the monitoring light and the oscillation light. Depending on the actual value of the multiplexer/demultiplexer distribution ratio, the coupling ratio can also be adjusted.

### Modifications

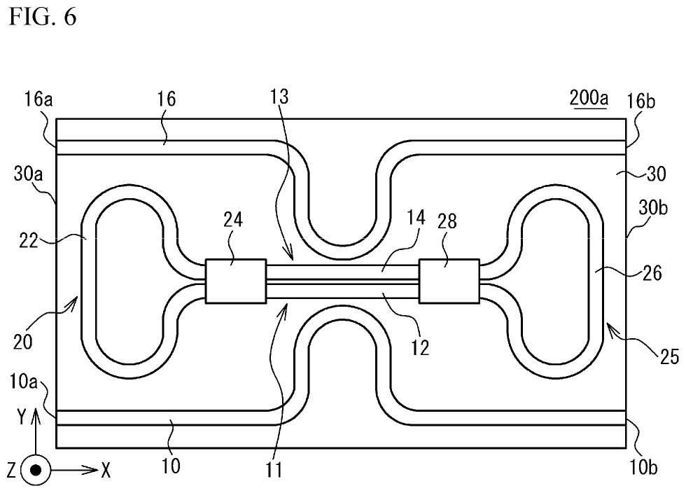

FIG. 6 is a plan view illustrating an optical filter 200a according to a first modification. Waveguides 12 and 14 are not curved and extend in parallel along the X-axis direction. Other configurations are the same as those in FIG. 3.

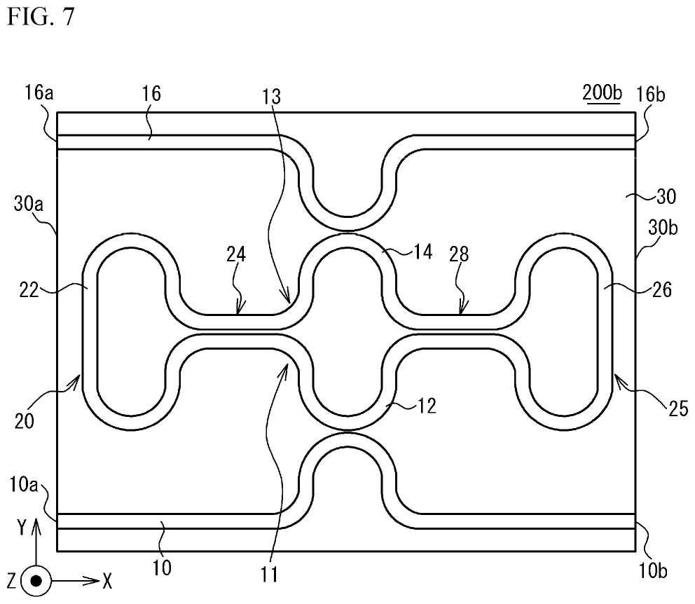

FIG. 7 is a plan view illustrating an optical filter 200b according to a second modification. As multiplexer/demultiplexer 24 and multiplexer/demultiplexer 28, directional couplers are used instead of the MMIs. In the directional coupler, two optical waveguides come close to each other at a distance of about a wavelength of light. The directional coupler distributes light similar to the 2×2 MMI coupler. Other configurations are the same as those in FIG. 3.

### Third Embodiment

FIG. 8 is a plan view illustrating a wavelength tunable laser element 300 according to a third embodiment. Description of the same configuration as that of the first embodiment or the second embodiment is omitted. As illustrated in FIG. 8, wavelength tunable laser element 300 includes a gain section 40 and a filter element 310. Filter element 310 is a passive element formed of Si or the like, and includes substrate 30.

Gain section 40 is a light emitting device formed of a group III-V compound semiconductor, and is butt-joined to an end portion 30a of substrate 30 of filter element 310 to be optically coupled to filter element 310. A reflection mirror 59 is provided on a side of gain section 40 opposite to filter element 310. Reflection mirror 59 is, for example, a distributed Bragg reflector (DBR). Gain section 40 and reflection mirror 59 form a monolithically integrated device.

(Filter Element)

Filter element 310 includes a waveguide 15, a multiplexer/demultiplexer 17, and two optical filters 200-1 and 200-2. Each of optical filters 200-1 and 200-2 has the same configuration as optical filter 200 illustrated in FIG. 6. Optical filter 200-1 includes access waveguides 10-1 and 16-1. Optical filter 200-2 includes access waveguides 10-2 and 16-2. Optical filter 200-1 and optical filter 200-2 are arranged in the Y-axis direction.

Waveguide 15 extends in the X-axis direction. A first end portion of waveguide 15 is located at the end portion 30a of substrate 30. A second end portion of waveguide 15 is optically coupled to an input end of multiplexer/demultiplexer 17. Multiplexer/demultiplexer 17 is, for example, a 3-dB 1×2 MMI coupler. One end portion of access waveguide 10-1 of optical filter 200-1 is optically coupled to a first output end of multiplexer/demultiplexer 17. One end portion of access waveguide 10-2 of optical filter 200-2 is optically coupled to a second output end of multiplexer/demultiplexer 17.

An end portion 10c of access waveguide 10-1, an end portion 10d of access waveguide 10-2, an end portion 16b of access waveguide 16-1, and an end portion 16d of access waveguide 16-2 are located in the end portion 30b of substrate 30. An end portion 16a of access waveguide 16-1 and an end portion 16c of access waveguide 16-2 are located at the end portion 30a of substrate 30.

Since an optical path length of a loop waveguide of optical filter 200-1 is different from an optical path length of a loop waveguide of optical filter 200-2, an FSR of optical filter 200-1 is different from an FSR of optical filter 200-2.

Electrode 35 (phase adjustment unit) is provided in each of two loop waveguides of optical filter 200-1, access waveguide 10-1, and two loop waveguides of optical filter 200-2. In the optical waveguides of optical filters 200-1 and 200-2, portions where electrode 35 is not provided have the same configuration as that of FIG. 1B.

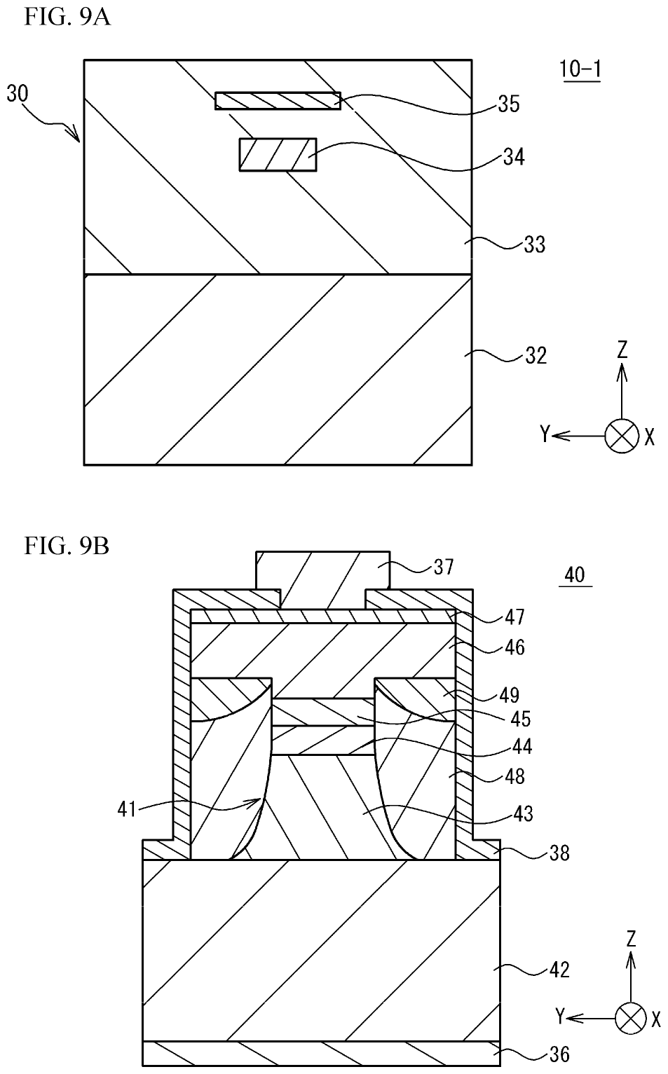

FIG. 9A is a cross-sectional view taken along line B-B of FIG. 8 and illustrates a cross-section of access waveguide 10-1 of optical filter 200-1. Description of the same configuration as FIG. 1B of the first embodiment will be omitted. As illustrated in FIG. 9A, waveguide core 34 and electrode 35 are embedded in cladding layer 33 in this order above substrate 32. Electrode 35 is spaced apart from waveguide core 34 and located above waveguide core 34. Electrode 35 is formed of a metal such as an alloy (nichrome) of nickel (Ni) and chromium (Cr), and functions as a heater. When a current flows through electrode 35, electrode 35 generates heat. When waveguide core 34 is heated by electrode 35, the refractive index of waveguide core 34 changes, and the phase of light propagating through waveguide core 34 can be adjusted. Each portion of the optical waveguide in filter element 310 where electrode 35 is provided has the same configuration as the 9A of FIG. 5.

(Gain Section)

FIG. 9B is a cross-sectional view taken along line C-C of FIG. 8, illustrating the cross-section of gain section 40. As illustrated in FIG. 9B, gain section 40 includes a substrate 42, cladding layers 43, 45, and 46, an active layer 44, a contact layer 47, an embedding layer 48, and a current blocking layer 49. Active layer 44 of gain section 40 is located at the same height as waveguide core 34 of waveguide 15 and faces waveguide core 34.

Cladding layer 43, active layer 44, and cladding layer 45 are sequentially stacked on an upper surface of substrate 42, and these semiconductor layers form a mesa 41. Mesa 41 protrudes from substrate 42 in the Z-axis direction and extends in the X-axis direction. A width of an upper end of mesa 41 in the Y-axis direction is, for example, 1.5 μm. Embedding layers 48 are provided on both sides of mesa 41 in the Y-axis direction. Current blocking layer 49 is provided on embedding layer 48. Two embedding layers 48 and two current blocking layers 49 sandwich mesa 41 from both sides in the Y-axis direction. A width from the side of one embedding layer 48 to the side of the other embedding layer 48 is, for example, 3 μm. Cladding layer 46 and contact layer 47 are stacked in this order on cladding layer 45 and on current blocking layer 49. A height from the upper surface of substrate 42 to an upper surface of contact layer 47 is, for example, 3 μm.

An insulation film 38 covers the upper surface of substrate 42, side surfaces of mesa 41, and the upper surface of mesa 41. Insulation film 38 has an opening on the upper surface of mesa 41. An electrode 37 is provided on mesa 41 and in contact with the upper surface of contact layer 47 exposed from the opening of insulation film 38. An electrode 36 is provided on a bottom surface of substrate 42 opposite to mesa 41.

Substrate 42, cladding layer 43, and current blocking layer 49 are formed of, for example, n-type indium phosphide (InP). Cladding layers 45 and 46 are formed of, for example, p-type InP. Contact layer 47 is formed of, for example, p-type indium gallium arsenide (InGaAs). Active layer 44 includes, for example, a plurality of well layers and barrier layers alternately stacked, and has a multi quantum well (MQW) structure. The well layer and the barrier layer are formed of undoped indium gallium arsenide phosphide (i-InGaAsP), for example. The semiconductor layers may be formed of a group III-V compound semiconductor other than those described above.

Insulation film 38 is formed of an insulator such as silicon nitride (SiN). Electrode 36 is an n-type electrode formed of a stacked body (Au/Ge/Ni) in which gold, germanium, and nickel are stacked in this order from substrate 42, for example. Electrode 37 is, for example, a p-type electrode formed of a stacked body (Ti/Pt/Au) in which titanium, platinum, and gold are laminated in order from contact layer 47.

By applying a voltage to electrodes 36 and 37, a current is injected into gain section 40. Since the n-type substrate 42, the p-type embedding layer 48, the n-type current blocking layer 49, and the p-type cladding layer 46 are stacked on both outsides of mesa 41, the current does not easily flow to the outside of mesa 41 but selectively flows to mesa 41. When current is injected into active layer 44, gain section 40 emits light.

As indicated by an arrow A7 in FIG. 8, light incident on filter element 310 from gain section 40 propagates through waveguide 15, and is divided into access waveguide 10-1 and access waveguide 10-2 by multiplexer/demultiplexer 17. When light propagates through access waveguide 10-1, a resonance mode is excited in optical filter 200-1, and light is reflected in access waveguide 10-1. When light propagates through access waveguide 10-2, a resonance mode is excited in optical filter 200-2, and light is reflected in access waveguide 10-2. The reflected light from optical filter 200-1 and the reflected light from optical filter 200-2 are multiplexed by multiplexer/demultiplexer 17 and propagate through waveguide 15 as indicated by an arrow A8. By the light being repeatedly reflected between filter element 310 and reflection mirror 59, wavelength tunable laser element 300 performs laser oscillation.

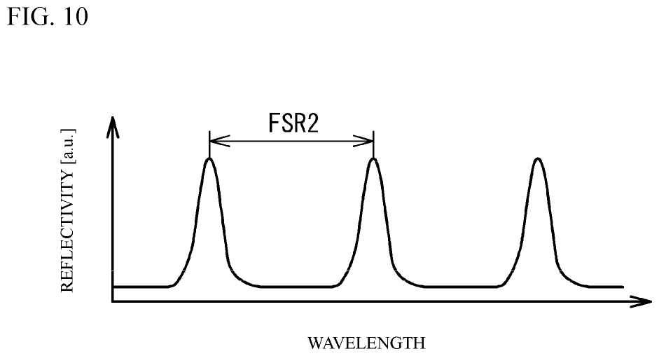

The FSR of the reflection spectrum of optical filter 200-1 is different from the FSR of the reflection spectrum of optical filter 200-2. The FSR of optical filter 200-1 is, for example, the FSR1 illustrated in FIG. 2A and FIG. 2B. FIG. 10 is a diagram illustrating a reflection characteristics of optical filter 200-2. The FSR2 of optical filter 200-2 is larger than the FSR1 of optical filter 200-1. The vernier effect by the two optical filters 200-1 and 200-2 is used to perform laser oscillation. Wavelength tunable laser element 300 performs laser oscillation at a wavelength at which the resonance wavelength of optical filter 200-1 coincides with the resonance wavelength of optical filter 200-2. As indicated by arrows A9 and A10 in FIG. 8, the laser light propagates through access waveguides 10-1 and 10-2 and are emitted from end portions 10c and 10d to the outside of wavelength tunable laser element 300. The laser light does not propagate through access waveguides 16-1 or 16-2.

Light is emitted from gain section 40, and light is incident on access waveguides 16-1 and 16-2 from a light source outside wavelength tunable laser element 300. Resonance modes are excited in optical filters 200-1 and 200-2, and reflected lights are reflected into access waveguides 16-1 and 16-2. For example, as indicated by an arrow A11, light is incident from end portion 16a of access waveguide 16-1. As indicated by an arrow A12, the reflected light of optical filter 200-1 is emitted from end portion 16a. As indicated by an arrow A13, the transmitted light of optical filter 200-1 is emitted from end portion 16b. As indicated by arrows A14 and A15, when light is incident from end portion 16c of access waveguide 16-2, reflected light of optical filter 200-2 is emitted from end portion 16c. As indicated by an arrow A16, the transmitted light of optical filter 200-2 is emitted from end portion 16d.

The resonance wavelength of the resonance mode and FSR occurring in access waveguide 16-1 coincide with the resonance wavelength of the resonance mode and FSR occurring in access waveguide 10-1. The resonance wavelength and FSR of the resonance mode occurring in access waveguide 16-2 coincide with the resonance wavelength of the resonance mode and FSR occurring in access waveguide 10-2. For example, the characteristics of optical filters 200-1 and 200-2 can be monitored by measuring the spectra of the transmitted light of optical filter 200-1 propagating through access waveguide 16-1 and the transmitted light of optical filter 200-2 propagating through access waveguide 16-2. The reflected light propagating through access waveguide 10-1 and the reflected light propagating through access waveguide 10-2 are not used for monitoring the characteristics but are used for laser oscillation.

According to the third embodiment, gain section 40 is butt-joined to filter element 310 and is optically coupled to access waveguide 10-1 of optical filter 200-1 and access waveguide 10-2 of optical filter 200-2. Light is incident on optical filters 200-1 and 200-2 from gain section 40 through access waveguides 10-1 and 10-2, and light is reflected from optical filters 200-1 and 200-2 to gain section 40. Laser oscillation is possible by reflecting light between reflection mirror 59 and each of optical filters 200-1 and 200-2.

It is possible to monitor the characteristics of optical filter 200-1 using light propagating through access waveguide 16-1 and monitor the characteristics of optical filter 200-2 using light propagating through access waveguide 16-2. The output light of gain section 40 does not propagate through access waveguides 16-1 or 16-2, and the reflected lights and transmitted lights of the optical filters propagate through access waveguides 16-1 and 16-2. The characteristics of optical filters 200-1 and 200-2 can be directly monitored independently of the laser oscillation. By adjusting the characteristics of optical filters 200-1 and 200-2, the oscillation wavelength of wavelength tunable laser element 300 can be accurately controlled.

The optical path length can be changed by passing a current through electrode 35 to heat the first access waveguide 10-1 and the loop waveguide. Since the optical path length is changed by the change of the refractive index, the phase of light can be adjusted. The wavelengths of the reflected lights from optical filters 200-1 and 200-2 can be adjusted. Since the relationship between the current flowing through electrode 35 and the refractive index is linear, the refractive index can be controlled with high accuracy.

For example, waveguide core 34 may be deteriorated due to heating by electrode 35. In such a case, the characteristics of optical filters 200-1 and 200-2 may change over time. According to the third embodiment, it is possible to monitor the characteristics of optical filters 200-1 and 200-2 and detect a change in the characteristics such as a shift in the resonance wavelength. The resonance wavelength is controlled by adjusting the voltage applied to electrode 35 in response to the change of the characteristics. Wavelength tunable laser element 300 can perform laser oscillation at a wavelength at which the reflectivity of optical filters 200-1 and 200-2 peaks. It is possible to accurately and stably control the oscillation wavelength.

Light can be entered into access waveguide 16-1 from either one of end portions 16a and 16b. Light can be entered into access waveguide 16-2 from either one of end portions 16c and 16d. Electrode 35 may be provided in access waveguide 10-2, for example. Although filter element 310 is formed of SOI substrate and has an optical waveguide of silicon, it may be formed of, for example, a compound semiconductor other than silicon.

### Fourth Embodiment

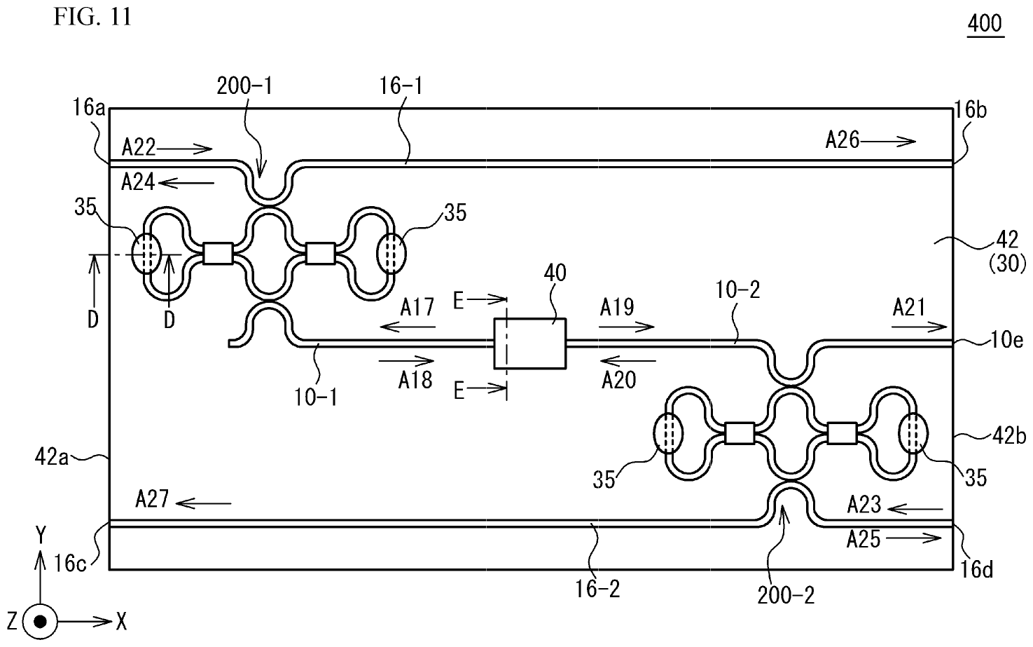

FIG. 11 is a plan view illustrating a wavelength tunable laser element 400 according to a fourth embodiment. Description of the same configuration as that of any one of the first embodiment to the third embodiment will be omitted. In wavelength tunable laser element 400, gain section 40 and two optical filters 200-1 and 200-2 are monolithically integrated on one substrate 42. Gain section 40 has the same configuration as FIG. 9B. One end portion of substrate 42 in the X-axis direction is referred to as an end portion 42a, and the other end portion is referred to as an end portion 42b.

As illustrated in FIG. 11, in the X-axis direction, optical filter 200-1 is located on one side of gain section 40, and optical filter 200-2 is located on the other side. Access waveguide 10-1 of optical filter 200-1 and access waveguide 10-2 of optical filter 200-2 face each other in the X-axis direction. One end portion of access waveguide 10-1 is optically coupled to gain section 40. The other end portion of access waveguide 10-1 does not reach the end portion 42a of substrate 42. One end portion 10e of access waveguide 10-2 is located at an end portion 42b of substrate 42 and functions as an emission port of wavelength tunable laser element 400. The other end portion of access waveguide 10-2 is optically coupled to gain section 40.

End portion 16a of access waveguide 16-1 of optical filter 200-1 and end portion 16c of access waveguide 16-2 of optical filter 200-2 are located at the end portion 42a of substrate 42. End portion 16b of access waveguide 16-1 and end portion 16d of access waveguide 16-2 are located at the end portion 42b of substrate 42. The FSR of optical filter 200-1 is different from the FSR of optical filter 200-2.

FIG. 12 is a cross-sectional view taken along line D-D of FIG. 11, and illustrates a cross-section of a portion of the loop waveguide of optical filter 200-1 where electrode 35 is provided. As illustrated in FIG. 12, a cladding layer 50, a core layer 51, and a cladding layer 52 are stacked in this order on the upper surface of substrate 42. Cladding layer 50, core layer 51, and cladding layer 52 form a high-mesa type optical waveguide. Core layer 51 is located at the same height as active layer 44 of gain section 40. Widths of cladding layer 50, core layer 51, and cladding layer 52 in the Y-axis direction are equal to the width of mesa 41 of gain section 40, for example, 1.5 μm. A height from the upper surface of substrate 42 to an upper surface of cladding layer 52 is, for example, 3 μm.

Insulation film 38 covers the upper surface of substrate 42, side surfaces of cladding layer 50, core layer 51 and cladding layer 52, and the upper surface of cladding layer 52. Electrode 35 is provided above cladding layer 52 and on an upper surface of insulation film 38. Electrode 36 is provided on a back surface of substrate 42 opposite to cladding layer 50.

Cladding layer 50 is formed of, for example, n-type InP. Core layer 51 is formed of, for example, InGaAsP. Cladding layer 52 is formed of, for example, p-type InP. Insulation film 38 is formed of, for example, SiN. Electrode 35 is formed of a metal such as nichrome. A portion of the optical waveguides of optical filters 200-1 and 200-2 where electrode 35 is provided has the same configuration as that of FIG. 12. A portion of the optical waveguide in which electrode 35 is not provided has a configuration obtained by removing electrode 35 from FIG. 12.

By applying a voltage to electrodes 36 and 37 and injecting a current into gain section 40, gain section 40 emits light. As indicated by arrows A17 and A19 in FIG. 11, light is emitted from both ends of gain section 40 in the X-axis direction and propagates through access waveguides 10-1 and 10-2. As indicated by arrows A18 and A20, optical filters 200-1 and 200-2 reflect light toward gain section 40 side. As light is repeatedly reflected by the two optical filters 200-1 and 200-2, wavelength tunable laser element 400 performs laser oscillation. The oscillation wavelength is determined by the vernier effect of the two optical filters 200-1 and 200-2. As indicated by an arrow A21, the laser light is emitted from end portion 10e of access waveguide 10-2 to the outside of wavelength tunable laser element 400. By adjusting the phase of light in optical filters 200-1 and 200-2 using electrode 35, the oscillation wavelength can be changed.

As indicated by an arrow A22 in FIG. 11, light from an external light source enters access waveguide 16-1 of optical filter 200-1 through end portion 16a. As indicated by an arrow A23, light is incident on access waveguide 16-2 of optical filter 200-2 through end portion 16d. Light having the resonance wavelength is reflected by optical filters 200-1 and 200-2. As indicated by arrows A24 and A25, the reflected light is emitted from end portion 16a or 16d. Light having a wavelength other than the resonance wavelength is transmitted through optical filters 200-1 and 200-2. As indicated by arrows A26 and A27, the transmitted light is emitted from end portion 16b or 16c. The characteristics of optical filters 200-1 and 200-2 can be monitored using transmitted light or reflected light propagating through access waveguides 16-1 and 16-2.

According to the fourth embodiment, gain section 40 and the two optical filters 200-1 and 200-2 are monolithically integrated. The output light of gain section 40 propagates through access waveguides 10-1 and 10-2 and is reflected by optical filters 200-1 and 200-2. When light is reflected by optical filters 200-1 and 200-2, wavelength tunable laser element 400 performs laser oscillation. It is possible to monitor the characteristics of optical filter 200-1 using light propagating through access waveguide 16-1 and monitor the characteristics of optical filter 200-2 using light propagating through access waveguide 16-2. The oscillation wavelength can be accurately and stably controlled by monitoring the characteristics of optical filters 200-1 and 200-2 independently of the laser oscillation.

As illustrated in FIG. 12, an optical waveguide having a high-mesa structure is covered with insulation film 38 made of SiN, so that loss of light can be suppressed. In particular, by using a loop waveguide having a high-mesa structure, it is possible to suppress loss of light.

### Fifth Embodiment

A plan view of the wavelength tunable laser element according to a fifth embodiment is the same as that of FIG. 11. A description of the same configuration as that of any one of the first to fourth embodiments will be omitted. In the fifth embodiment, gain section 40 and two optical filters 200-1 and 200-2 are monolithically integrated on one substrate 30, instead of substrate 42 in the fourth embodiment. The configurations of optical filters 200-1 and 200-2 are the same as those in FIG. 3. A portion of the optical waveguide in which electrode 35 is provided has the same configuration as that of FIG. 9A. A portion of the optical waveguide in which electrode 35 is not provided has the same configuration as that of FIG. 1B.

Access waveguide 10-1 of optical filter 200-1 and access waveguide 10-2 of optical filter 200-2 form one optical waveguide. The access waveguide shared by optical filter 200-1 and optical filter 200-2 may be referred to as access waveguide 10-1. Gain section 40 is provided above access waveguide 10-1.

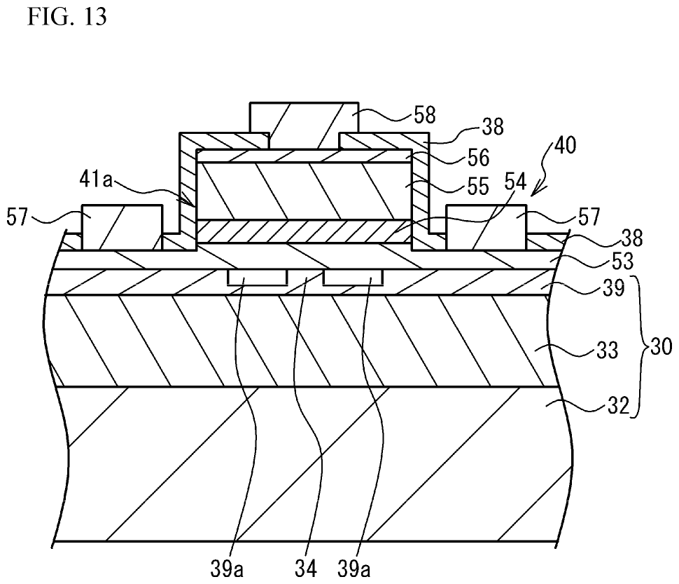

FIG. 13 is a cross-sectional view taken along line E-E of FIG. 11, illustrating a cross-section of gain section 40 and access waveguide 10-1. As illustrated in FIG. 13, substrate 30 is an SOI substrate and includes substrate 32, cladding layer 33 (box layer), and a silicon layer 39. Substrate 32, cladding layer 33, and Si layer 39 are stacked in this order in the Z-axis direction. A thickness of Si layer 39 is, for example, 0.22 μm. Waveguide core 34 is provided in Si layer 39. A width of waveguide core 34 is, for example, 0.5 μm. In Si layer 39, recessed portions 39a are provided on both sides of waveguide core 34 in the Y-axis direction. A bottom surface of recessed portion 39a is formed by Si layer 39. On the outside of recessed portion 39a, Si layer 39 having the same thickness as waveguide core 34 spreads. Gain section 40 is bonded to the surface of Si layer 39 opposite to cladding layer 33. The wavelength tunable laser element in the fifth embodiment is a hybrid type laser element.

Gain section 40 includes a cladding layer 53, a cladding layer 55, an active layer 54, and a contact layer 56. Cladding layer 53 is bonded to the upper surface of Si layer 39 of substrate 30. Active layer 54, cladding layer 55, and contact layer 56 are stacked in this order on cladding layer 53. Active layer 54, cladding layer 55, and contact layer 56 protrude in the Z-axis direction and form a mesa 41a having a height of, for example, 2 μm. Cladding layer 53 extends outside mesa 41a in the XY plane. Gain section 40 overlaps waveguide core 34 and recessed portions 39a in the Z-axis direction. Cladding layer 53 of gain section 40 and Si layer 39 of substrate 30 may be in contact directly with each other. An insulation film may be provided between cladding layer 53 and Si layer 39. Gain section 40 may have a tapered portion along the access waveguide on the access waveguide.

Insulation film 38 covers the upper surface of substrate 30, the upper surface of cladding layer 53 and mesa 41a. Insulation film 38 has an opening above contact layer 56 and an opening above cladding layer 53. Two electrodes 57 are located on both sides of mesa 41a and provided on the upper surface of cladding layer 53 exposed from the openings of insulation film 38. An electrode 58 is provided on the upper surface of contact layer 56 exposed from the opening of insulation film 38.

Cladding layer 53 is formed of, for example, n-type InP. Active layer 54 is formed of, for example, aluminum gallium indium arsenide (AlGaInAs) and has a multiple quantum well structure. Cladding layer 55 is formed of, for example, p-type InP. Contact layer 56 is formed of, for example, p-type InGaAs. Electrode 57 is formed of a metal such as a stacked body of gold, germanium, and nickel (Au/Ge/Ni). Electrode 58 is formed of a metal such as a stacked body of titanium, platinum, and gold (Ti/Pt/Au).

According to the fifth embodiment, the output light of gain section 40 propagates through access waveguides 10-1 and 10-2 and is reflected by optical filters 200-1 and 200-2. Wavelength tunable laser element 400 performs laser oscillation. It is possible to monitor the characteristics of optical filter 200-1 using light propagating through access waveguide 16-1 and monitor the characteristics of optical filter 200-2 using light propagating through access waveguide 16-2. The oscillation wavelength can be accurately and stably controlled by monitoring the characteristics of optical filters 200-1 and 200-2 independently of the laser oscillation.

### Sixth Embodiment

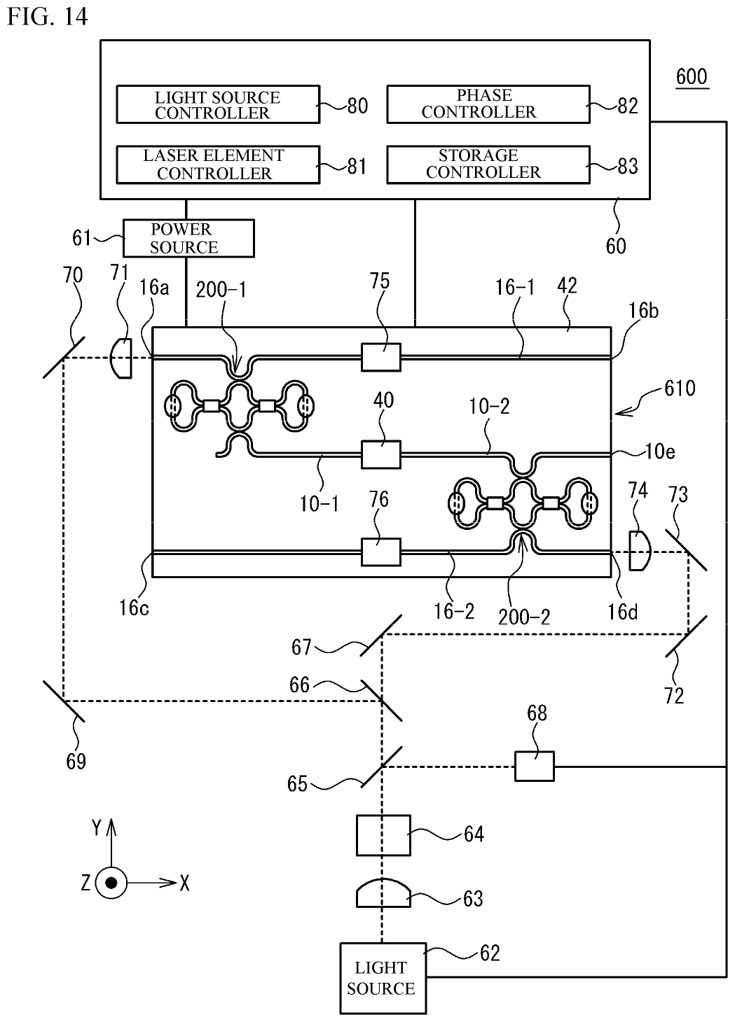

FIG. 14 is a diagram illustrating wavelength tunable laser module 600 according to a sixth embodiment. Wavelength tunable laser module 600 includes a wavelength tunable laser element 610, a controller 60, a power source 61, and a light source 62.

Wavelength tunable laser element 610 has the same configuration as the wavelength tunable laser element according to the fourth embodiment or the fifth embodiment, and includes light-receiving elements 75 and 76. Optical filters 200-1 and 200-2, gain section 40, and light-receiving elements 75 and 76 are monolithically integrated on substrate 42 or substrate 30. Light-receiving element 75 is provided in the middle of access waveguide 16-1 of optical filter 200-1 and is optically coupled to access waveguide 16-1. Light-receiving element 76 is provided in the middle of access waveguide 16-2 of optical filter 200-2 and is optically coupled to access waveguide 16-2. Light-receiving elements 75 and 76 may be provided outside of wavelength tunable laser element 610.

Light source 62 is, for example, a wavelength tunable laser element. The dotted line in FIG. 14 indicates the path of light emitted from light source 62. A lens 63, an isolator 64, a beam splitter 65, a half mirror 66, and a mirror 67 are disposed in this order from the side closer to light source 62 along the Y-axis direction, and lens 63 faces a light emission port of light source 62.

A light-receiving element 68 faces beam splitter 65 in the X-axis direction. Each of light-receiving elements 68, 75, and 76 includes a photodiode and outputs an electric signal (current) corresponding to the intensity of light incident on each photodiode.

A mirror 69 faces half mirror 66 in the X-axis direction. A mirror 70 faces half mirror 69 in the Y-axis direction and faces a lens 71 and end portion 16a of access waveguide 16-1 in the X-axis direction. Mirror 70, lens 71, and end portion 16a are arranged in this order.

A mirror 72 faces mirror 67 in the X-axis direction. A mirror 73 faces half mirror 72 in the Y-axis direction, and faces a lens 74 and end portion 16d of access waveguide 16-2 in the X-axis direction. End portion 16d, lens 74, and mirror 73 are arranged in this order.

Light emitted from light source 62 is sequentially incident on lens 63, isolator 64, beam splitter 65, half mirror 66, and mirror 67. Beam splitter 65 reflects a part of light towards light-receiving element 68. Light-receiving element 68 outputs a current dependent on the intensity of light.

Half mirror 66 reflects a part of light toward mirror 69. Light is reflected by mirrors 69 and 70, passes through lens 71, and enters access waveguide 16-1 from end portion 16a. Light-receiving element 75 outputs a current corresponding to the intensity of light transmitted through optical filter 200-1.

Light passing through beam splitter 65 and half mirror 66 is reflected by mirrors 67, 72, and 73, passes through lens 74, and enters access waveguide 16-2 through end portion 16d. Light-receiving element 76 outputs a current corresponding to the intensity of light transmitted through optical filter 200-2.

Controller 60 is a control device including, for example, a computer. Controller 60 is electrically connected to power source 61, light source 62 and light-receiving elements 68, 75 and 76. Controller 60 functions as a light source controller 80, a laser element controller 81, a phase controller 82, and a storage controller 83.

Light source controller 80 switches on and off light of light source 62 and controls the wavelength of light. Phase controller 82 controls the phase and wavelength of light propagating through wavelength tunable laser element 610 by controlling the voltage applied from the power supply 61 to electrode 35 of wavelength tunable laser element 610. Laser element controller 81 controls a voltage applied from the power supply 61 to gain section 40 of wavelength tunable laser element 610. Storage controller 83 controls a storage device 86 and performs writing and reading of data.

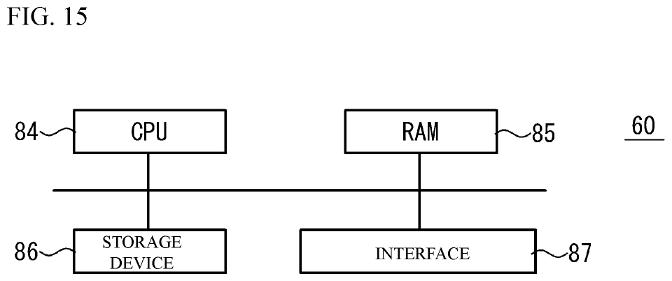

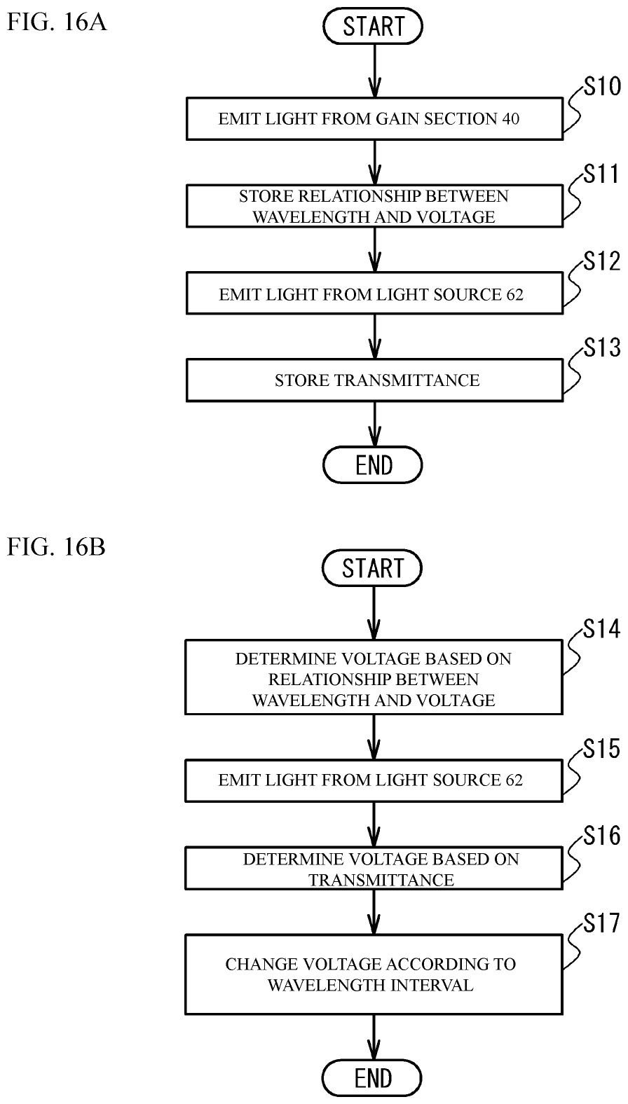

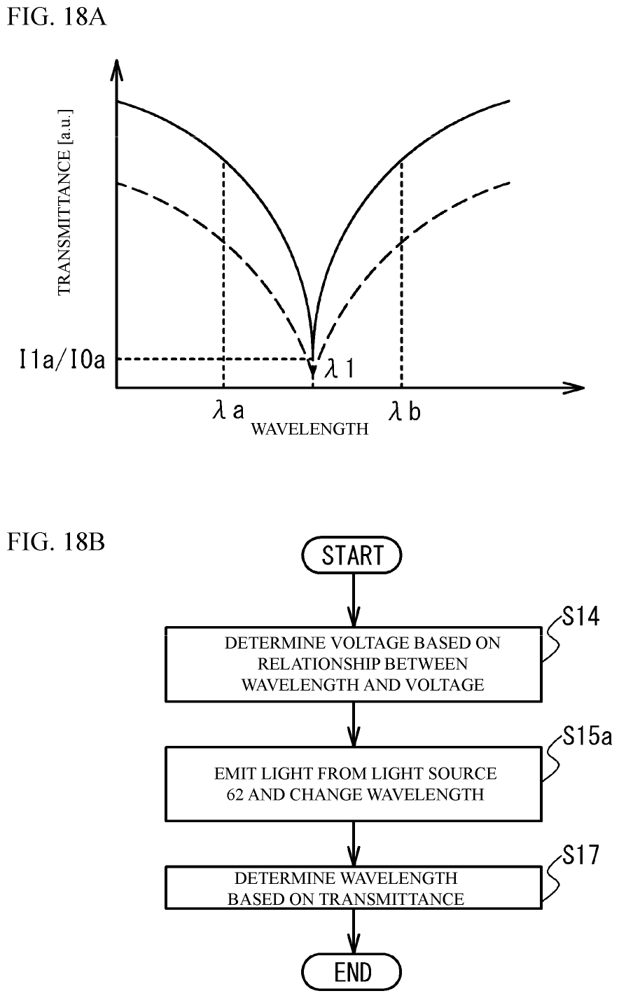

FIG. 15 is a block diagram illustrating the hardware configuration of controller 60. As illustrated in FIG. 15, controller 60 includes a central processing unit (CPU) 84, a random access memory (RAM) 85, storage device 86, and an interface 87. CPU 84, RAM 85, storage device 86, and interface 87 are connected to each other via a bus or the like. RAM 85 is a volatile memory that temporarily stores programs, data, and the like. Storage device 86 is, for example, a read only memory (ROM), a solid state drive (SSD) such as a flash memory, a hard disk drive (HDD), or the like. Storage device 86 stores a data table to be described later, a program for processing illustrated in FIG. 16A, FIG. 16B, and FIG. 18, and the like.

When CPU 80 executes a program stored in RAM 86, light source controller 80, laser element controller 81, phase controller 82, and storage controller 83 illustrated in FIG. 14 are implemented in controller 60. Each unit of controller 60 may be hardware such as a circuit.

FIGS. 16A and 16B are flowcharts illustrating processes performed by controller 60. The process of FIG. 16A is performed, for example, as an inspection during manufacturing of wavelength tunable laser element 610.

As illustrated in FIG. 16A, laser element controller 81 injects current into gain section 40 of wavelength tunable laser element 610 using power supply 61, and causes light to be emitted from gain section 40 (step S10). The wavelength of light emitted from end portion 10e of access waveguide 10-2 is measured by a wavelength meter (not illustrated). Phase controller 82 applies a voltage to electrode 35 using power supply 61. When a current flows through electrode 35, the wavelength of light propagating through wavelength tunable laser element 610 changes. Phase controller 82 acquires the wavelength of light and controls the voltage so that the wavelength becomes a desired value. The above operation is repeated for a plurality of wavelengths. Storage controller 83 causes storage device 86 to store the relationship between wavelengths and voltages (step S11). Table 1 shows an example of the relationship between wavelength and voltage. Storage device 86 stores a table such as Table 1.

TABLE 1

| WAVELENGTH | λ1 | λ2 | λ3 | . . . |
|---|---|---|---|---|
| VOLTAGE | V1 | V2 | V3 | . . . |

Light source controller 80 causes light source 62 to emit light (step S12). The wavelengths of light are λm1, λm2, λm3, and the like. These wavelengths are, for example, wavelengths in the vicinity of the wavelengths described in Table 1, and are preferably wavelengths in a range in which the transmittance rapidly changes depending on wavelength. Light emitted from light source 62 is incident on light-receiving element 68 and access waveguides 16-1 and 16-2 of wavelength tunable laser element 610. The transmitted light of optical filter 200-1 is incident on light-receiving element 75. The transmitted light of optical filter 200-2 is incident on light-receiving element 76. Light-receiving element 68 outputs a current I0 corresponding to the intensity of light immediately after being emitted from light source 62. Light-receiving element 75 outputs a current I1 corresponding to the intensity of light transmitted through optical filter 200-1. Light-receiving element 75 outputs a current I2 corresponding to the intensity of the light transmitted through optical filter 200-2.

Phase controller 82 applies a voltage corresponding to each wavelength in Table 1 to electrode 35. Storage controller 83 acquires values of currents I0, I1, and I2 for each of the wavelengths, and calculates the transmittances I1/I0 of optical filter 200-1 and I2/I0 of optical filter 200-2. Storage controller 83 stores the transmittances for the respective wavelengths in storage device 86 (step S13). Table 2 shows an example of the transmittance for each wavelength. Thus, the process of FIG. 16A ends.

TABLE 2

| WAVELENGTH | λm1 | λm2 | λm3 | . . . |
|---|---|---|---|---|
| TRANSMITTANCE | I1a/I0a | I1b/I0b | I1c/I0c | . . . |
| OF OPTICAL FILTER 200-1 | | | | |
| TRANSMITTANCE | I2a/I0a | I2b/I0b | I2c/I0c | . . . |
| OF OPTICAL FILTER 200-2 | | | | |

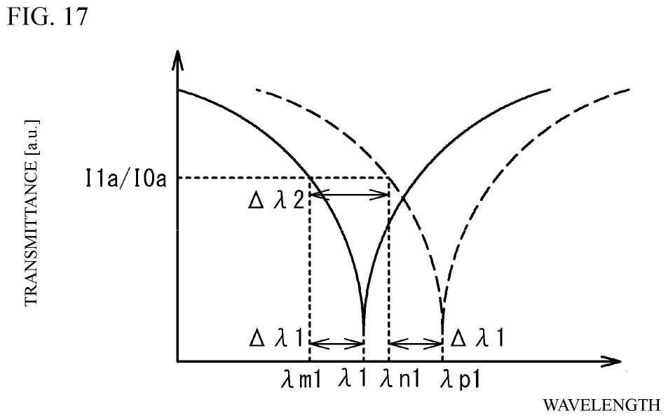

FIG. 17 is a diagram illustrating a spectrum of transmittance. The horizontal axis represents the wavelength. The vertical axis represents the transmittance of the optical filter. For example, the transmittance may shift from a solid line to a broken line due to aging or the like. In the example of the solid line in FIG. 17, the transmittance is minimized at the wavelength λ1. At wavelength λm1, the transmittance is I1a/I0a. In the example of the broken line, the transmittance becomes minimal at the wavelength λp1. The transmittance is I1a/I0a at wavelength λn1. By the shift of transmittance, the transmittance values corresponding to the wavelengths change, but the shape of the spectrum does not change. In the example of the solid line, the interval between the wavelength XI at which the transmittance becomes minimal and the wavelength λm1 at which the transmittance becomes I1a/I0a is Δλ1. Also in the example of the broken line, the interval between the wavelength λp1 at which the transmittance becomes the minimal and the wavelength λn1 at which the transmittance becomes I1a/I0a is also Δλ1.

The process of FIG. 16B is performed, for example, when operating wavelength tunable laser element 610. It is assumed that the process of FIG. 16A has been performed so as to realize the transmittance indicated by the solid line in FIG. 17, and then the transmittance is shifted over time in wavelength by an amount of Δλ2 to the broken line in FIG. 17.

As illustrated in FIG. 16B, phase controller 82 determines a voltage to be applied to electrode 35 based on the relationship between wavelengths and voltages shown in Table 1, and applies the voltage to electrode 35 (step S14). Light source controller 80 causes light source 62 to emit light (step S15). Phase controller 82 acquires the transmittances I1/I0 and I2/I0 and determines a voltage based on the transmittances (step S16). Phase controller 82 controls the voltage applied to electrode 35 so that the transmittance becomes I1a/I0a shown in Table 2.

The transmittance spectrum has been shifted from the solid line to the broken line in FIG. 17. The wavelength corresponding to transmittance of I1a/I0a is λn1. An interval between the wavelengths λm1 and λ1 is Δλ2. The voltage applied to electrode 35 is changed by the amount corresponding to the interval Δλ2 between λm1 and Δλ1 (step S17). The resonance wavelengths are adjusted to wavelengths λm1 from the wavelengths Δλ1 separated by Δλ2, and the transmittances become minimal value at the wavelength of λ1. The characteristics of optical filter 200-1 are adjusted so that the transmittance reaches the minimal. The characteristics of optical filter 200-2 is also adjusted by the same processing. By this processing, as illustrated in FIG. 17, the transmittances of optical filters 200-1 and 200-2 become minimum, and each reflectivity thereof becomes maximum. The oscillation wavelength of wavelength tunable laser element 610 can be accurately and stably adjusted to λ1.

According to the sixth embodiment, light-receiving element 75 measures the intensity of the transmitted light of access waveguide 16-1 of optical filter 200-1. Light-receiving element 76 measures the intensity of light transmitted through access waveguide 16-2 of optical filter 200-2. The wavelengths of lights are controlled by adjusting the voltage applied to electrode 35 based on the light transmittance of optical filter 200-1 and the light transmittance of optical filter 200-2. The wavelength is controlled to λ1, which is the resonance wavelength of optical filters 200-1 and 200-2, for example. Wavelength tunable laser element 610 can lase at wavelength at which each reflectivity shows peak. In other words, the oscillation wavelength can be controlled based on the intensity of the transmitted light.

In the example of FIGS. 16A and 16B, characteristics of both optical filters 200-1 and 200-2 are controlled. The characteristics of optical filters 200-1 and 200-2 may be controlled independently. Wavelength tunable laser element 610 may have the configuration illustrated in FIG. 8.

### Modification

FIG. 18A is a diagram illustrating a transmittance spectrum. The solid line in FIG. 18A is the spectrum of the optical filter immediately after manufacturing of wavelength tunable laser element 610. Both the examples of the solid line and the broken line have a minimum value at the wavelength λ1. The broken line is a spectrum after the change with time, and the transmittance changes compared to the solid line. Even if the transmittance is set to the value (for example, I1a/I0a) obtained by the process of FIG. 16A immediately after manufacturing, the wavelength may not necessarily become the desired value λ1.

FIG. 18B is a flowchart illustrating processing executed by controller 60, which is performed during operation of wavelength tunable laser module 600 instead of the processing of FIG. 16B. The process of FIG. 16A is also implemented in a modification.

Phase controller 82 determines a voltage to be applied to electrode 35 based on the relationship between wavelengths and voltages shown in Table 1, and applies, for example, a voltage V1 corresponding to the wavelength λ1 to electrode 35 (step S14). Light source controller 80 causes light source 62 to emit light and swings the wavelength of the light in a range from λa to λb, for example, as illustrated in FIG. 18B (wavelength-dithering, step S15a). The wavelength λa is smaller than the wavelength λ1. The wavelength ab is greater than the wavelength λ1. Light source controller 80 acquires the transmittances I1/I0 and I2/I0, and determines wavelength of light emitted from light source 62 based on the transmittances (step S17). In other words, light source controller 80 controls the voltage applied to light source 62 so that the transmittance becomes the minimum value. Thus, the process ends. By this process, wavelength tunable laser element 610 can be laser-oscillated at the wavelength λ1 at which the transmittance becomes minimum and the reflectivity becomes maximum as illustrated in FIG. 18A.

According to the modification, the wavelength of light emitted from light source 62 is changed to find a wavelength at which the transmittance is minimized. It is possible to adjust the characteristics of optical filters 200-1 and 200-2 and control the oscillation wavelength even when the resonance wavelength is shifted or the value of the transmittance is changed.

### Seventh Embodiment

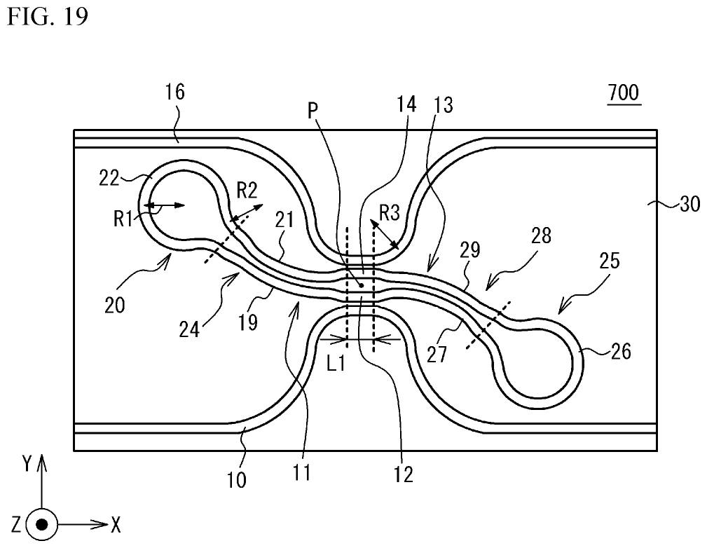

In a seventh embodiment, a directional coupler is used as a multiplexer/demultiplexer so that a wavelength dependence of the optical filter can be decreased and a crosstalk can be suppressed to a low level. FIG. 19 is a plan view illustrating an optical filter 700 according to the seventh embodiment. Description of the same configurations as those of the first to sixth embodiments will be omitted.

In the XY plane, optical filter 700 is point-symmetric with respect to the point P. Loop mirror 20 and multiplexer/demultiplexer 24 extend toward one vertex of substrate 30. Loop mirror 25 and multiplexer/demultiplexer 28 extend toward a vertex diagonally opposite to the vertex of substrate 30.

Loop waveguides 22 and 26 are, for example, arc-shaped. The curvature radius R1 of loop waveguides 22 and 26 is, for example, 15 μm. The curvature radius R2 of the connecting portion between the loop waveguide and the multiplexer/demultiplexer is, for example, 13.675 μm. The curvature radius R3 of the bent portions of access waveguides 10 and 16 is, for example, 15 μm. The lengths of the portions where access waveguide 10 and waveguide 12 are parallel to each other and the portions where access waveguide 16 and waveguide 14 are parallel to each other (lengths L1) are, for example, 2 μm.

Dotted lines in FIG. 19 are virtual line segments each indicating a boundary of multiplexer/demultiplexer 24 and multiplexer/demultiplexer 28 with other configurations. As illustrated in FIG. 19, multiplexer/demultiplexer 24 and multiplexer/demultiplexer 28 are directional couplers each having a degree of coupling of 3 dB. Multiplexer/demultiplexer 24 is convex downward in FIG. 19. Multiplexer/demultiplexer 28 is convex upward.

Multiplexer/demultiplexer 24 includes two waveguides 19 and 21. Waveguide 19 is connected to loop waveguide 22 and waveguide 12. Waveguide 21 is connected to loop waveguide 22 and waveguide 14. Multiplexer/demultiplexer 28 includes two waveguides 27 and 29. Waveguide 27 is connected to loop waveguide 26 and waveguide 12. Waveguide 29 is connected to loop waveguide 26 and waveguide 14.

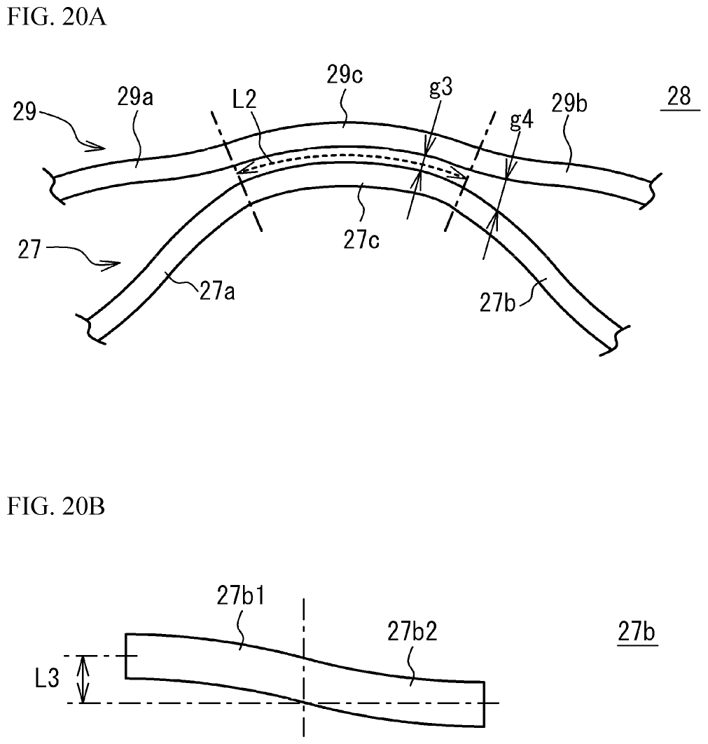

FIG. 20A is an enlarged view of multiplexer/demultiplexer 28. In waveguide 27, the side close to waveguide 12 (the left side in FIG. 20A) is referred to as a region 27a, the side close to loop waveguide 26 (the right side in FIG. 20A) is referred to as a region 27b, and the central portion is referred to as a region 27c. Waveguide 29 has regions 29a, 29b, and 29c similar to waveguide 27. Each width of the waveguides 27 and 29 is, for example, 0.4 μm. The width is constant in all regions.

Each of regions 27c and 29c has a curved shape such as an arc. The dotted line (dotted arrow) in FIG. 20A represents the middle line between region 27c and region 29c. The curvature radius of the dotted line is, for example, 30.5 μm. The length (arc length) L2 of the dotted line is, for example, several μm or several tens of μm.

Regions 27a, 27c, 29a, and 29c have shapes different from those of regions 27c and 29c, and are bend waveguides. As an example, regions 27a, 27c, 29a, and 29c are S-bends.

Waveguide 27 is disposed so as to move away from waveguide 29 in regions 27a and 27c. A distance (gap g3) between the waveguides 27 and 29 in the central portion (regions 27c and 29c) is, for example, 0.25 μm. Distances (gap g4) between the waveguides 27 and 29 in the S-bends (regions 27a, 29a, 27b, and 29c) are larger than gap g3. The gap g4 increases as the distance from the central portion increases, and is, for example, twice the gap g3 or more (e.g. 0.5 μm or more). Waveguide 19 of multiplexer/demultiplexer 24 has the point-symmetrical shape with waveguide 29 around the point P. Waveguide 21 of multiplexer/demultiplexer 24 has the point-symmetrical shape with waveguide 27 around the point P.

FIG. 20B is an enlarged view of region 27b. The left half of region 27b is referred to as a region 27b1, and the right half thereof is referred to as a region 27b2. The shape of 27b1 is point-symmetric with the shape of region 27b2, and is, for example, an arc. A length of 27b1 is the same as a length of region 27b2. A curvature radius of 27b1 and a curvature radius of region 27b2 are, for example, 15 μm. A length L3 between the centers of region 27b1 and region 27b2 is, for example, 1 μm. The shape of region 27b1 may be different from the shape of region 27b2. In other words, one waveguide of the multiplexer/demultiplexer may be symmetric or asymmetric.

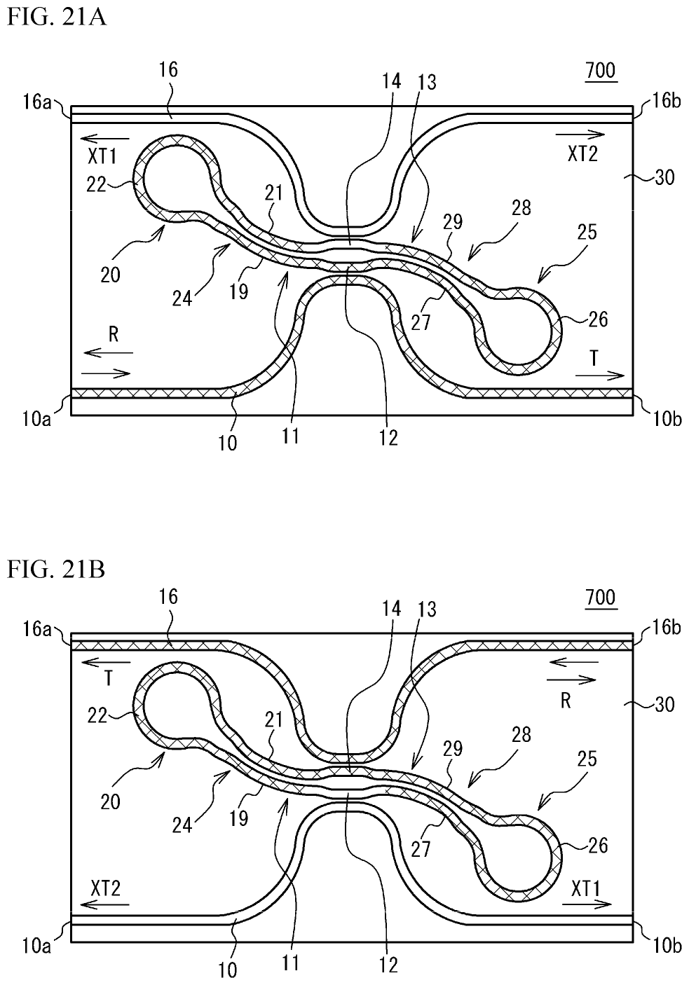

FIG. 21A and FIG. 21B are diagrams illustrating optical filter 700, and are examples in which light is incident from an access waveguide. A portion where the electromagnetic field is distributed is illustrated with a lattice pattern. In FIG. 21A, light is incident from the left end (end portion 10a) of access waveguide 10. The resonance mode of resonator 11 is excited. The reflected light R is reflected toward end portion 10a of access waveguide 10. The transmitted light T propagates toward end portion 10b of access waveguide 10.

Ideally, light which propagates through the loop waveguide counterclockwise and incidents on waveguide 12 and light which propagates in the loop waveguide clockwise and incidents on waveguide 12 are at the same phase as each other, and interfere each other constructively. On the other hand, light which propagates through the loop waveguide counterclockwise and incidents on waveguide 14 and light which propagates through the loop waveguide clockwise and incidents on waveguide 14 have opposite phases, and interfere each other destructively. That is, the resonance mode of resonator 11 propagates through waveguide 12 and access waveguide 10, but does not propagate through waveguide 14 or access waveguide 16. However, light may leak into waveguide 14 and access waveguide 16. Light leaking into waveguide 14 and propagating toward end portion 16a of access waveguide 16 is referred to as a crosstalk XT1. Light leaking into waveguide 14 and propagating toward end portion 16b of access waveguide 16 is referred to as a crosstalk XT2.

In FIG. 21B, light is incident from the right end portion 16b of access waveguide 16. The resonance mode of resonator 13 is excited. The reflected light R is reflected toward end portion 16a of access waveguide 16. The transmitted light T propagates toward end portion 16b of access waveguide 16. Light may leak into waveguide 12 and access waveguide 10. Light propagating toward end portion 10b of access waveguide 10 is referred to as a crosstalk XT1. Light propagating toward end portion 10a of access waveguide 10 is referred to as a crosstalk XT2.

As described in the second embodiment and the like, light in a resonance mode is extracted from one of access waveguides 10 and 16, and the characteristics of optical filter 700 are monitored using light propagating through the other. It is important to suppress crosstalk between two access waveguides low. Crosstalk occurs due to an imbalance in the distribution of light in the multiplexer/demultiplexer.

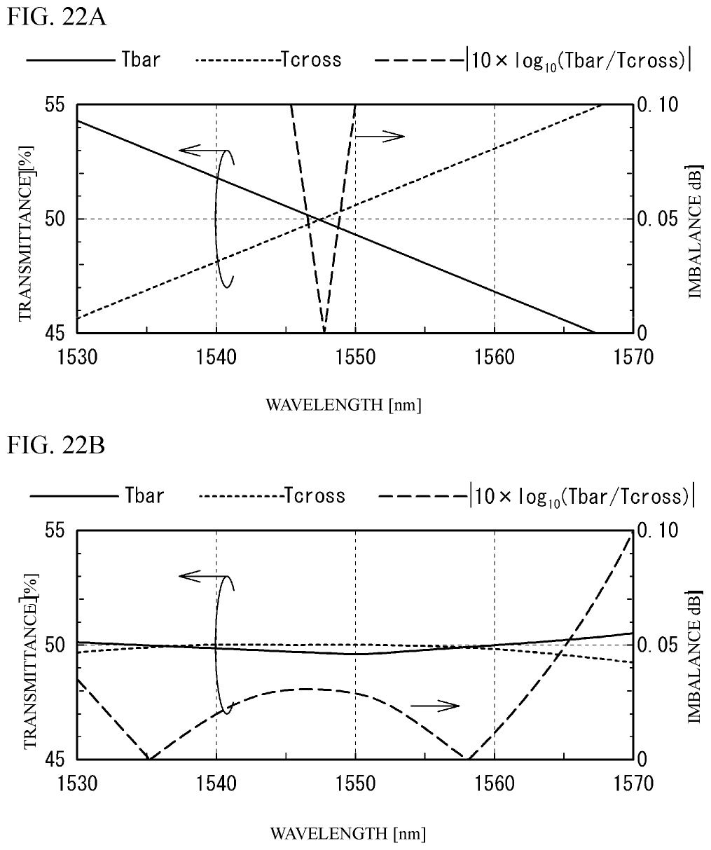

FIGS. 22A and 22B illustrate the characteristics of multiplexer/demultiplexers. FIGS. 22A and 22B are simulation results. Thar denotes a transmittance of light to one waveguide and Tcross denotes a transmittance of light to the other waveguide when light is incident on one of two waveguides of a multiplexer/demultiplexer, and Tbar/Tcross denotes a distribution ratio. The horizontal axis represents wavelengths of light, and is the range from 1530 nm to 1570 nm. The left vertical axis represents the transmittance of light to each waveguide. The right vertical axis represents the light imbalance between the two waveguides. The solid line in the figure represents Thar. The dotted line represents Tcross. The broken line represents the imbalance.

The imbalance is the absolute value of the common logarithm (10×log₁₀ (Tbar/Tcross)) of the distribution ratio. In the case light is distributed in the two waveguides in the same ratio (Tbar=Tcross), the imbalance is 0. In the case one of Thar and Tcross is greater than the other, the imbalance increases. The refractive index of the waveguide core is 2.76, and the refractive index of the cladding layer is 1.44. A gap g1 between access waveguide 10 and waveguide 12 and a gap g2 between access waveguide 16 and waveguide 14 are 200 nm (see FIG. 3).

FIG. 22A is an example in which two linear waveguides function as a directional coupler. The simulation assuming a straight waveguide is performed by setting the curvature radius of dotted line in FIG. 20A to infinity. The length of the linear waveguide is 3.88 μm. As illustrated in FIG. 22A, Tbar and Tcross are equal to 50% at a wavelength of 1547.5 nm. The imbalance becomes 0 at 1547.5 nm. As the wavelength becomes shorter, Tcross becomes smaller and Tbar becomes larger. As the wavelength becomes longer, Thar becomes smaller and Tcross becomes larger. The farther the wavelengths are apart from 1547.5 nm, the more the imbalance increases and exceeds 0.1 dB in bands of wavelengths 1545 nm or below and 1550 nm or over.

As illustrated in FIG. 22A, Tbar is high and Tcross is low in a band of wavelengths shorter than 1547.5 nm. In such a band of wavelength, when light is incident from access waveguide 10, light propagating counterclockwise in loop waveguide 26 (corresponding to Thar) is strong, and light propagating clockwise in loop waveguide 26 (corresponding to Tcross) is weak. Therefore, these lights do not cancel each other out, propagate to waveguide 14, and transit to access waveguide 16. Light propagating through loop waveguide 22 also does not cancel each other. In a band of wavelengths longer than 1547.5 nm, Thar is low and Tcross is high. Light propagating clockwise in loop waveguide 26 is strong, and light propagating counterclockwise in loop waveguide 26 is weak. Therefore, light propagates to waveguide 14 without being canceled. When light is incident from access waveguide 16, light also propagates through waveguide 12 and leaks into access waveguide 10.

FIG. 22B is an example where two waveguides have bends at both ends such as multiplexer/demultiplexer 28 of FIG. 20A. The dotted line in FIG. 20A has a curvature radius of 30.5 μm and the length L2 of 10.8 μm. The gaps g1 and g2 are 200 nm. In the example of FIG. 21B, in a band of wavelengths from 1530 nm to 1570 nm, Thar and Tcross are within 50%±1%. The imbalance between the waveguides is 0.1 dB or less in above band of wavelengths.

For example, when light is incident from access waveguide 10, the intensity of light propagating counterclockwise in loop waveguide 26 is substantially the same as the intensity of light propagating clockwise in loop waveguide 26. Therefore, these lights cancel each other and does not easily propagate to waveguide 14. The two lights propagating through loop waveguide 22 also cancel each other, and are less likely to propagate through waveguide 14. Light that transitions from waveguide 14 to access waveguide 16 is also suppressed. When light is incident from access waveguide 16, light hardly propagates to waveguide 12 and hardly leaks to access waveguide 10.

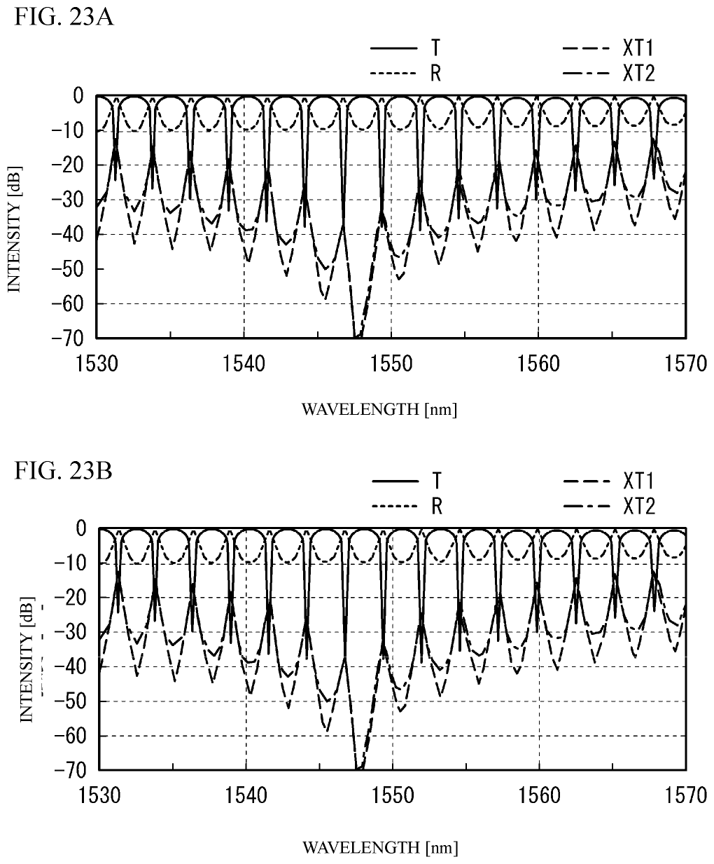

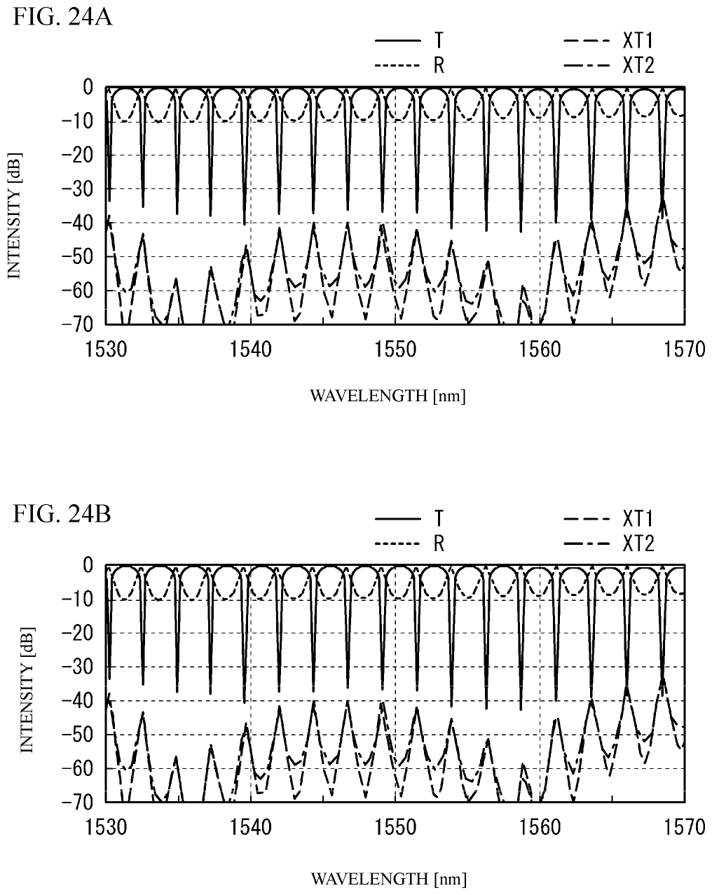

FIG. 23A to FIG. 24B are diagrams illustrating frequency characteristics of optical filters. The horizontal axis represents the wavelength of light. The vertical axis represents the intensity of light. The solid line in the figure represents the intensity of the transmitted light T. The dotted line represents the intensity of reflected light R. The broken line represents the intensity of crosstalk XT1. The alternate long and short dash line represents the intensity of the crosstalk XT2.

FIG. 23A and FIG. 23B are examples in which the multiplexer/demultiplexer is formed by two linear waveguides, and correspond to the example of FIG. 22A. In FIG. 23A, light is incident from access waveguide 10. In FIG. 23B, light is incident from access waveguide 16.

As illustrated in FIGS. 23A and 23B, the transmittance intensity becomes local minimum and the reflection intensity becomes local maximum at the resonance frequencies (i.e. resonance wavelengths). Crosstalk XT1 and crosstalk XT2 become local maximum at the resonance frequencies. In the range of wavelengths from about 1545 nm to 1553 nm, crosstalk XT1 and XT2 are −30 dB or less. However, when the wavelengths are shorter than 1545 nm or longer than 1553 nm, crosstalk XT1 and XT2 are −30 dB or more.

As illustrated in FIG. 22A, light is distributed unequally in the multiplexer/demultiplexer. When light is incident from access waveguide 10, light also propagates to access waveguide 16. When light is incident from access waveguide 16, light also propagates to access waveguide 10. As illustrated in FIG. 23A and FIG. 23B, the crosstalk XT1 and XT2 increase.

FIGS. 24A and 24B are examples in which the multiplexer/demultiplexer has a bend as illustrated in FIG. 20A, and correspond to the example of FIG. 22B. In FIG. 24A, light is incident from access waveguide 10. In FIG. 24B, light is incident from access waveguide 16. As illustrated in FIGS. 24A and 24B, crosstalk XT1 and XT2 are suppressed to −30 dB or less over the band from 1530 nm to 1570 nm.

As illustrated in FIG. 22B, light is distributed at a nearly equal ratio in the multiplexer/demultiplexer. When light enters from access waveguide 10, it is difficult for light to propagate to access waveguide 16. When light enters from access waveguide 16, it is difficult for light to propagate to access waveguide 10. As illustrated in FIGS. 24A and 24B, the wavelength dependence of crosstalk can be suppressed, and the crosstalk can be suppressed to be low in a wide wavelength band.

According to the seventh embodiment, multiplexer/demultiplexer 24 is a directional coupler having two waveguides 19 and 21. Multiplexer/demultiplexer 28 is a directional coupler having two waveguides 27 and 21. In each of the multiplexer/demultiplexer 24 and multiplexer/demultiplexer 28, the distance between the waveguides changes. As illustrated in FIG. 20A, gap g4 in regions 29a and 29b at both ends of multiplexer/demultiplexer 28 is larger than gap g3 in region 29c at the center of multiplexer/demultiplexer 28. Also in multiplexer/demultiplexer 24, the gaps in the regions at both ends are larger than the gap in the central portion.

A phase mismatch occurs between light propagating through waveguide 19 of multiplexer/demultiplexer 24 and light propagating through waveguide 21 of multiplexer/demultiplexer 24 when waveguides 19 and 21 include regions having a curved shape. A phase mismatch occurs between light propagating through the waveguide 27 of multiplexer/demultiplexer 28 and light propagating through waveguide 29 of multiplexer/demultiplexer 28 when waveguides 27 and 29 include regions having a curved shape. As illustrated in FIG. 22B, the transmittances Thar and Tcross of light from the multiplexer/demultiplexer to the loop waveguide are around 50% over the band of wavelengths from 1530 nm to 1570 nm. The wavelength dependence of light distribution is improved. Since lights circulating around the loop waveguide cancel each other, crosstalk is suppressed to be low. More specifically, as illustrated in FIGS. 24A and 24B, the wavelength dependence of crosstalk can be reduced and crosstalk can be suppressed to be low over a wide wavelength band. Two resonance modes can be independently generated in a wide band, and for example, oscillation of laser light and monitoring of characteristics can be simultaneously performed.

As illustrated in FIG. 20A, multiplexer/demultiplexer 28 has arc-shaped regions 27c and 29c in the center. Multiplexer/demultiplexer 28 has regions 27a and 29a in one end portion and regions 27b and 29b in the opposite end portion. Region 27a, 27c, 29a and 29c are S-bends. Multiplexer/demultiplexer 24 has an arcuate region and S-bends similar to multiplexer/demultiplexer 28. Gap g3 in the S-bend is larger than gap g4 between the two waveguides in the central region. Light can be equally distributed over a wide wavelength band. The crosstalk can be suppressed to be low.

As illustrated in FIG. 20A, gap g4 at each of the bends at both ends is larger than gap g3 between the two waveguides at the central portion of the multiplexer/demultiplexer. Gap g4 increases as the distance from the central portion increases, and may be, for example, twice or more, three times or more than gap g3.

The shape of the multiplexer/demultiplexer is not limited to the example of FIG. 20A. The region at the center may be an arc or a curve other than an arc. The S-bend is a shape like connecting two circular arcs. The S-bend may be, for example, a sine curve. The regions at both ends of the multiplexer/demultiplexer may be S-bends or bends other than S-bends. The waveguides of the multiplexer/demultiplexer may have bends of different shapes. For example, in the waveguide 27 of multiplexer/demultiplexer 28, region 27a and region 27b may have different shapes.

Optical filter 700 is point-symmetric with respect to a point P illustrated in FIG. 19. Multiplexer/demultiplexer 24 is convex downward, and multiplexer/demultiplexer 28 is convex upward. Light input from waveguide 12 to multiplexer/demultiplexer 24 propagates through waveguide 19 bulging on the outer peripheral side of multiplexer/demultiplexer 24. Light input from waveguide 12 to multiplexer/demultiplexer 28 propagates through waveguide 27 bulging toward the inner peripheral side of multiplexer/demultiplexer 28. Light input from waveguide 14 to multiplexer/demultiplexer 24 propagates through the inner peripheral side of waveguide 21 of multiplexer/demultiplexer 24. Light input from waveguide 14 to multiplexer/demultiplexer 28 propagates on the outer peripheral side of waveguide 29 of multiplexer/demultiplexer 28. The amount of phase change of light passing through loop mirrors 20 and 25 and returning to waveguide 12 matches the amount of phase change of light passing through loop mirrors 20 and 25 and returning to waveguide 14. The resonance wavelength of resonator 11 matches the resonance wavelength of resonator 13. The FSR of resonator 11 coincides with the FSR of resonator 13.

The finesse of the resonator can be controlled by adjusting the gap between access waveguide 10 and waveguide 12 (corresponding to distance g1 in FIG. 3) and the gap between access waveguide 16 and waveguide 14 (corresponding to distance g2 in FIG. 3). The finesse can also be controlled by adjusting the lengths L1 of portions where access waveguide 10 and waveguide 12 are parallel and where access waveguide 16 and waveguide 14 are parallel.

As illustrated in FIG. 22B, light is nearly equally divided in a band including the entire C-band (wavelengths from 1530 nm to 1565 nm), and crosstalk is suppressed to be low as illustrated in FIGS. 24A and 24B. Characteristics can be improved in other wavelength bands by changing the length of the waveguide or the like. The waveguide of optical filter 700 may be an optical waveguide having a Si-waveguide core as illustrated in FIG. 1B, or an optical waveguide having a high-mesa structure formed of a group III-V compound semiconductor as illustrated in FIG. 12. The waveguide may be provided with an electrode for phase adjustment. Optical filter 700 may be incorporated into the wavelength tunable laser element.

Although the embodiments of the present disclosure have been described in detail above, the present disclosure is not limited to the specific embodiments, and various modifications and changes can be made within the scope of the present disclosure described in the claims.

What is claimed is:

1. An optical filter comprising:
a first loop mirror;
a second loop mirror;
a first waveguide optically coupled to the first loop mirror and the second loop mirror; and
a first access waveguide,
wherein the first loop mirror includes a first loop waveguide and a first multiplexer/demultiplexer,
wherein the second loop mirror includes a second loop waveguide and a second multiplexer/demultiplexer,
wherein the first loop waveguide is optically coupled to the first multiplexer/demultiplexer,
wherein the second loop waveguide is optically coupled to the second multiplexer/demultiplexer,
wherein the first waveguide is optically coupled to the first multiplexer/demultiplexer and the second multiplexer/demultiplexer, and
wherein the first access waveguide is optically coupled to the first waveguide.

2. The optical filter according to claim 1, comprising:
a second waveguide optically coupled to the first loop mirror and the second loop mirror; and
a second access waveguide,
wherein the second waveguide is optically coupled to the first multiplexer/demultiplexer and the second multiplexer/demultiplexer, and
wherein the second access waveguide is optically coupled to the second waveguide.

3. The optical filter according to claim 2, wherein a shape of the first multiplexer/demultiplexer is symmetrical, a shape of the second multiplexer/demultiplexer is symmetrical, and a shape of the first waveguide and a shape of the second waveguide are symmetrical to each other.

4. The optical filter according to claim 2, wherein the first multiplexer/demultiplexer and the second multiplexer/demultiplexer are 2×2 multi-mode interference waveguides or directional couplers.

5. The optical filter according to claim 2,
wherein the first multiplexer/demultiplexer and the second multiplexer/demultiplexer are directional couplers each including two waveguides,
wherein a distance between the two waveguides of the first multiplexer/demultiplexer on a side of the first loop waveguide and the distance on a side of the first waveguide and the second waveguide are greater than the distance in a central part of the first multiplexer/demultiplexer, and
wherein a distance between the two waveguides of the second multiplexer/demultiplexer on a side of the second loop waveguide and the distance on a side of the first waveguide and the second waveguide are greater than the distance in a central part of the second multiplexer/demultiplexer.

6. The optical filter according to claim 5,
wherein the two waveguides of the first multiplexer/demultiplexer have a bend on the side of the first loop waveguide and have a bend on the side of the first waveguide and the second waveguide, and
wherein the two waveguides of the second multiplexer/demultiplexer have a bend on the side of the second loop waveguide and have a bend on the side of the first waveguide and the second waveguide.

7. The optical filter according to claim 5, wherein the central part of the two waveguides of the first multiplexer/demultiplexer is curvilinear.

8. The optical filter according to claim 2, comprising a phase adjusting section disposed in at least one of the first loop waveguide and the second loop waveguide, the phase adjusting section being configured to adjust a phase of light propagating in the at least one of the first loop waveguide and the second loop waveguide.

9. The optical filter according to claim 2, wherein the first waveguide, the second waveguide, the first loop waveguide, the second loop waveguide, the first access waveguide, and the second access waveguide are formed of silicon.

10. The optical filter according to claim 2,
wherein the first waveguide, the second waveguide, the first loop waveguide, the second loop waveguide, the first access waveguide, and the second access waveguide include a mesa,
wherein the mesa includes a first cladding layer, a core layer and a second cladding layer,
wherein the first cladding layer, the core layer and the second cladding layer are formed of a group III-V compound semiconductor, and
wherein the first cladding layer, the core layer and the second cladding layer are stacked in this order to form the mesa.

11. The optical filter according claim 8, wherein the phase adjustment unit is a heater that generates heat in response to an electric signal inputted on the heater.

12. A wavelength tunable laser element comprising:
a gain section; and
two optical filters,
wherein the two optical filters are the optical filters each according to claim 8,
wherein intervals between resonant wavelengths of the two optical filters differ from each other, and
wherein the gain section has an optical gain and is optically coupled to the first access waveguide of each of the two optical filters.

13. The wavelength tunable laser element according to claim 12,
wherein the two optical filters are formed on a substrate,
wherein the gain section and the substrate are butt joined to each other, and
wherein the wavelength tunable laser element comprises a reflection mirror disposed opposite to the substrate with respect to the gain section.

14. The wavelength tunable laser element according to claim 12, comprising:
a substrate made of a III-V group compound semiconductor,
wherein the gain section and the two optical filters are monolithically integrated on the substrate,
wherein a first one of the two optical filters is positioned on a side of a first end portion of the gain section, and
wherein a second one of the two optical filters is positioned on a side of a second end portion of the gain section.

15. The wavelength tunable laser element according to claim 12,
wherein the two optical filters are formed on a substrate,
wherein the first waveguide, the second waveguide, the first loop waveguide, the second loop waveguide, the first access waveguide, and the second access waveguide are silicon waveguides formed on the substrate,
wherein a first one of the two optical filters is positioned on a side of a first end portion of the gain section,
wherein a second one of the two optical filters is positioned on a side of a second end portion of the gain section, and
wherein the gain section is joined to a surface of the substrate.

16. A wavelength tunable laser module comprising:
the wavelength tunable laser element according to claim 12;
a light source configured to emit light into a second access waveguide of the wavelength tunable laser element; and
a light-receiving element optically coupled to a second access waveguide of the wavelength tunable laser element.

17. A method of controlling the wavelength tunable laser module according to claim 16, comprising:
a step of emitting light from the light source into a second access waveguide of the wavelength tunable laser element; and
a step of controlling, based on an intensity of light passing through the second access waveguide, a wavelength of light propagating in the second access waveguide.

18. The method of controlling the wavelength tunable laser module according to claim 17, wherein the step of controlling the wavelength of light is a step of controlling, based on the intensity of light passing through the second access waveguide, the wavelength of light propagating in the second access waveguide by using the phase adjusting section.

19. The method of controlling the wavelength tunable laser module according to claim 17, wherein the step of controlling the wavelength of light is a step of controlling the wavelength of light propagating in the second access waveguide by controlling, based on the intensity of light passing through the second access waveguide, the wavelength of light emitted from the light source.

20. A computer-readable, non-transitory medium storing a program for controlling the wavelength tunable laser module according to claim 16 that causes a computer to execute a process, the process comprising the steps of:
emitting light from a light source into a second access waveguide of the wavelength tunable laser element; and
controlling, based on an intensity of light passing through the second access waveguide, a wavelength of light propagating in the second access waveguide.
